(19) United States
(12) Patent Application Publication
(10) Pub. No.: US 2018/0364297 A1
(43) Pub. Date: Dec. 20, 2018

(54) SEMICONDUCTOR DEVICE AND METHOD OF TESTING SEMICONDUCTOR DEVICE

(71) Applicant: Renesas Electronics Corporation, Tokyo (JP)

(72) Inventors: Yoshihide NAKAMURA, Ibaraki (JP); Kenji SHIOZAWA, Ibaraki (JP); Tetsuya KOKUBUN, Tokyo (JP); Yutaka NAKADAI, Tokyo (JP); Takuya LEE, Tokyo (JP)

(73) Assignee: Renesas Electronics Corporation, Tokyo (JP)

(21) Appl. No.: 16/005,859

(22) Filed: Jun. 12, 2018

(30) Foreign Application Priority Data
Jun. 20, 2017 (JP) 2017-120564

(51) Int. Cl. G01R 31/26; G01R 31/27

(52) U.S. Cl. CPC G01R 31/2644; G01R 31/27; G01R 31/2621

(57) ABSTRACT

A semiconductor device includes a bus, first and second bus drivers that drive the bus, and a control circuit that controls the first and second bus drivers. The control circuit controls the first and second bus drivers in such a way that the first and second bus drivers supply logic signals different from each other to the bus.

### CROSS-REFERENCE TO RELATED APPLICATIONS

This application is based upon and claims the benefit of priority from Japanese patent application No. 2017-120564, filed on Jun. 20, 2017, the disclosure of which is incorporated herein in its entirety by reference.

### BACKGROUND

The present disclosure relates to a semiconductor device and a method of testing a semiconductor device. For example, the present disclosure relates to a semiconductor device including a bus driver for driving a bus, and a method of testing a semiconductor device.

Commonly, a semiconductor device is subjected to an operation test before shipment to the market, and a semiconductor device that passed the operation test is shipped to the market. Conducting the operation test on the semiconductor device before shipment in this way can improve the reliability of the semiconductor device.

Japanese Unexamined Patent Application Publication No. 11-52019 discloses a technique for avoiding false detection when a scan test is conducted on a semiconductor device including a tri-state buffer to thereby improve a failure detection rate.

### SUMMARY

As described in the Background, in order to improve the reliability of the semiconductor device, an operation test is conducted on the semiconductor device before shipment to the market.

However, in recent years, as the integration of semiconductor devices has progressed, the operation test of a semiconductor device has tended to become complicated, and the time necessary for the operation test has tended to become longer. Therefore, requires a technique of simplifying the operation test of the semiconductor device and shortening the time necessary for the operation test is required.

Other problems of the related art and new features of the present disclosure will become apparent from the following descriptions of the specification and attached drawings.

An example aspect is a semiconductor device including first and second bus drivers connected to a bus. The first and second bus drivers are controlled to supply logic signals different from each other to the bus.

According to the above example aspect, it is possible to provide a semiconductor device and a method of testing a semiconductor device that can simplify the operation test of the semiconductor device and shorten the time required for the operation test

### BRIEF DESCRIPTION OF THE DRAWINGS

The above and other aspects, advantages and features will be more apparent from the following description of certain embodiments taken in conjunction with the accompanying drawings, in which:

FIG. 1 is a view for describing a semiconductor device according to a first embodiment;

FIG. 2 is a circuit diagram showing an example of a bus driver included in the semiconductor device according to the first embodiment;

FIG. 3 is a view for describing an operation of the semiconductor device according to the first embodiment;

FIG. 4 is a circuit diagram for describing the operation of the semiconductor device according to the first embodiment;

FIG. 5 is a timing chart for describing the operation of the semiconductor device according to the first embodiment;

FIG. 6 is a timing chart for describing an operation of a semiconductor device according to a comparative example;

FIG. 7 is a view for describing an operation test of a semiconductor device according to the comparative example;

FIG. 8 is a view for describing the operation test of the semiconductor device according to the comparative example;

FIG. 9 is a view for describing a semiconductor device according to a second embodiment;

FIG. 10 is a view for describing details of the semiconductor device according to the second embodiment;

FIG. 11 is a view showing an example of a test pattern of the semiconductor device according to the second embodiment;

FIG. 12 is a view for describing the semiconductor device according to the second embodiment;

FIG. 13 is a view for describing a semiconductor device according to a third embodiment;

FIG. 14 is a view showing an example of a test pattern of the semiconductor device according to the third embodiment;

FIG. 15 is a table for describing a determination result of the operation test of the semiconductor device according to the third embodiment;

FIG. 16 is a table for describing a determination result of the operation test of the semiconductor device according to the third embodiment;

FIG. 17 is a view for describing the semiconductor device according to the third embodiment;

FIG. 18 is a view for describing a semiconductor device according to a fourth embodiment;

FIG. 19 is a view for describing an operation of the semiconductor device according to the fourth embodiment;

FIG. 20 is a view for describing the operation of the semiconductor device according to the fourth embodiment;

FIG. 21 is a view for describing a semiconductor device according to a fifth embodiment;

FIG. 22 is a view for describing an operation of the semiconductor device according to the fifth embodiment;

FIG. 23 is a view for describing the operation of the semiconductor device according to the fifth embodiment; and

FIG. 24 is a view showing another configuration example of the semiconductor device according to the fifth embodiment.

### DETAILED DESCRIPTION

### First Embodiment

A first embodiment will be described below with reference to the drawings.

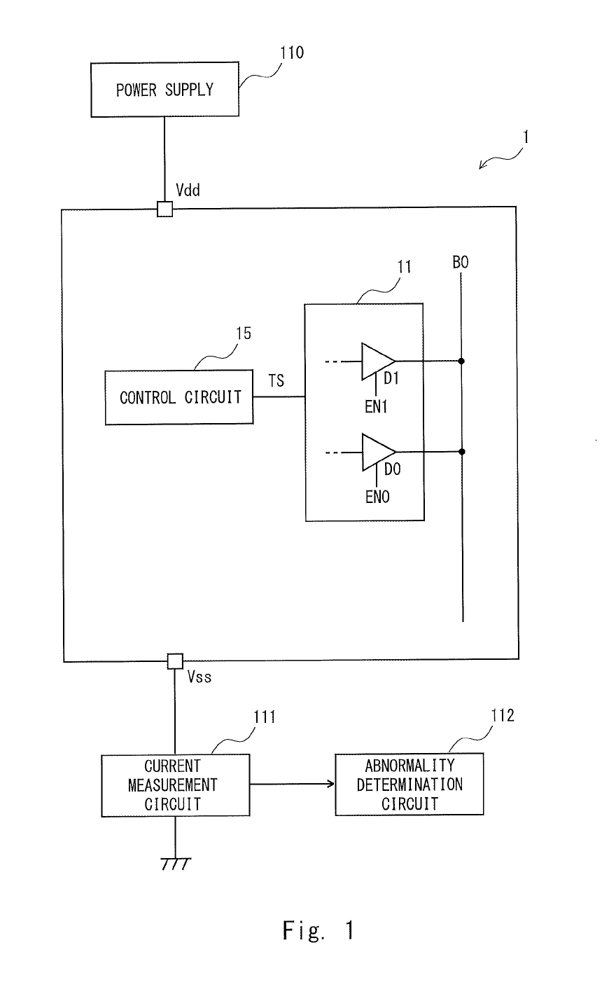

FIG. 1 is a view for describing a semiconductor device according to the first embodiment. As shown in FIG. 1, the semiconductor device 1 according to this embodiment includes at least a bus B0, a logic module 11, and a control circuit 15.

In the semiconductor device 1 shown in FIG. 1, only the components necessary for the description of this embodiment are described, and descriptions of other commonly known components are omitted. In this embodiment, for example, the semiconductor device 1 is, for example, a logic LSI and is a microcomputer manufactured using CMOS (Complementary Metal Oxide Semiconductor) technology.

Further, the semiconductor device 1 according to this embodiment detects an abnormality in the semiconductor device 1 by measuring a static power supply current (Iddq) of the semiconductor device 1. Therefore, in this embodiment, in order to conduct an operation test on the semiconductor device 1, a power supply 110 is connected to a power supply terminal Vdd on the high potential side of the semiconductor device 1, and a current measurement circuit 111 is connected to a power supply terminal Vss on the low potential side of the semiconductor device 1. Then, in a state where power is supplied from the power supply 110 to the power supply terminal Vdd of the semiconductor device 1, the static power supply current (Iddq), which flows when a logic state of an internal circuit of the semiconductor device 1 is fixed to a predetermined state, is measured using the current measurement circuit 111. Information about the measured amount of the static power supply current (Iddq) is supplied to an abnormality determination circuit 112. The abnormality determination circuit 112 determines whether the semiconductor device 1 is abnormal based on the amount of the static power supply current (Iddq).

As described above, in this embodiment, the power supply 110, the current measurement circuit 111, and the abnormality determination circuit 112, in addition to the semiconductor device 1, which constitute a semiconductor test system, are used to conduct the operation test on the semiconductor device 1. In the configuration shown in FIG. 1, the configuration in which the current measurement circuit 111 and the abnormality determination circuit 112 are provided outside the semiconductor device 1 has been described. However, in this embodiment, the current measurement circuit 111 and the abnormality determination circuit 112 may be provided inside the semiconductor device 1.

Hereinafter, the semiconductor device 1 according to this embodiment will be described in detail.

As shown in FIG. 1, the logic module 11 included in the semiconductor device 1 includes a plurality of bus drivers D0 and D1 for driving the bus B0. The bus driver D0 outputs a logic signal (hereinafter, a high-level signal is indicated as H, and a low-level signal is indicated as L) inside the logic module 11 to the bus B0. Likewise, the bus driver D1 outputs logic signals inside the logic module 11 to the bus B0. In other words, the bus drivers D0 and D1 function as output bus drivers for outputting the logic signals inside the logic module 11 to the bus B0. Note that descriptions of other circuit elements (a logic circuit, a driver for inputting signals from the bus, etc.) included in the logic module 11 are omitted.

For example, each of the bus drivers D0 and D1 may be composed of a tri-state buffer. That is, when an enable signal EN0 is at a high level, the bus driver D0 outputs the same logic signal as the logic signal input to the bus driver D0 to the bus B0. On the other hand, in the bus driver D0, when the enable signal EN0 is at a low level, an output signal of the bus driver D0 becomes high impedance. In this case, data is not output from the bus driver D0 to the bus B0. The same applies to the bus driver D1.

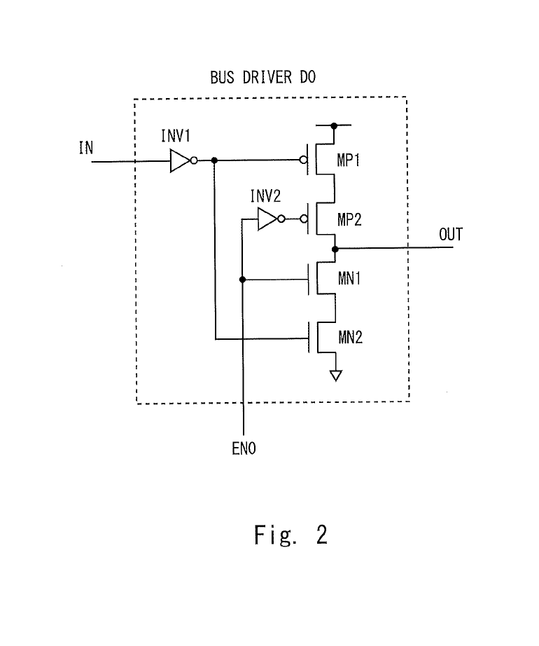

FIG. 2 is a circuit diagram showing an example of the bus driver D0. As shown in FIG. 2, the bus driver D0 can be composed of P-channel transistors MP1 and MP2, N-channel transistors MN1 and MN2, and inverters INV1 and INV2.

The source of the P-channel transistor MP1 is connected to a power supply line on the high potential side, and the drain of the P-channel transistor MP1 is connected to the source of the P-channel transistor MP2. The drain of the P-channel transistor MP2 is connected to an output terminal OUT of the bus driver D0. The drain of the N-channel transistor MN1 is connected to the output terminal OUT, and the source of the N-channel transistor MN1 is connected to the drain of the N-channel transistor MN2. The source of the N-channel transistor MN2 is connected to a power supply line on the low potential side.

An input of the inverter INV1 is connected to an input terminal IN of the bus driver D0. Further, the inverter INV1 supplies a signal obtained by inverting an input signal to the gate of the P-channel transistor MP1 and the gate of the N-channel transistor MN2.

An enable signal EN0 is supplied to an input of the inverter INV2. Further, the inverter INV2 supplies a signal obtained by inverting the enable signal EN0 to the gate of the P-channel transistor MP2. The enable signal EN0 is supplied to the gate of the N-channel transistor MN1.

When the enable signal EN0 is at the low level, the P-channel transistor MP2 and the N-channel transistor MN1 are turned off. In this case, the output terminal OUT of the bus driver D0 is in a floating state, resulting in a high impedance state.

On the other hand, when the enable signal EN0 is at the high level, the P-channel transistor MP2 and the N-channel transistor MN1 are turned on. In this state, when a high-level signal is supplied to the input terminal IN of the bus driver D0, a low-level signal is supplied to each the gate of the P-channel transistor MP1 and the gate of the N-channel transistor MN2. Accordingly, the P-channel transistor MP1 is turned on, and the N-channel transistor MN2 is turned off, and a high-level signal is output from the output terminal OUT of the bus driver D0. On the other hand, when a low-level signal is supplied to the input terminal IN of the bus driver D0, a high-level signal is supplied to each of the gate of the P-channel transistor MP1 and the gate of the N-channel transistor MN2. Then, the P-channel transistor MP1 is turned off, and the N-channel transistor MN2 is turned on, and a low-level signal is output from the output terminal OUT of the bus driver D0. The bus driver D1 has the same configuration as that shown in FIG. 2.

The control circuit 15 included in the semiconductor device 1 shown in FIG. 1 is configured to control the bus drivers D0 and D1. The control circuit 15 controls the bus drivers D0 and D1 by supplying a test signal TS to the logic module 11. Specifically, in a test mode, the control circuit 15 controls the bus drivers D0 and D1 so that the bus drivers D0 and D1 supply logic signals different from each other to the bus B0.

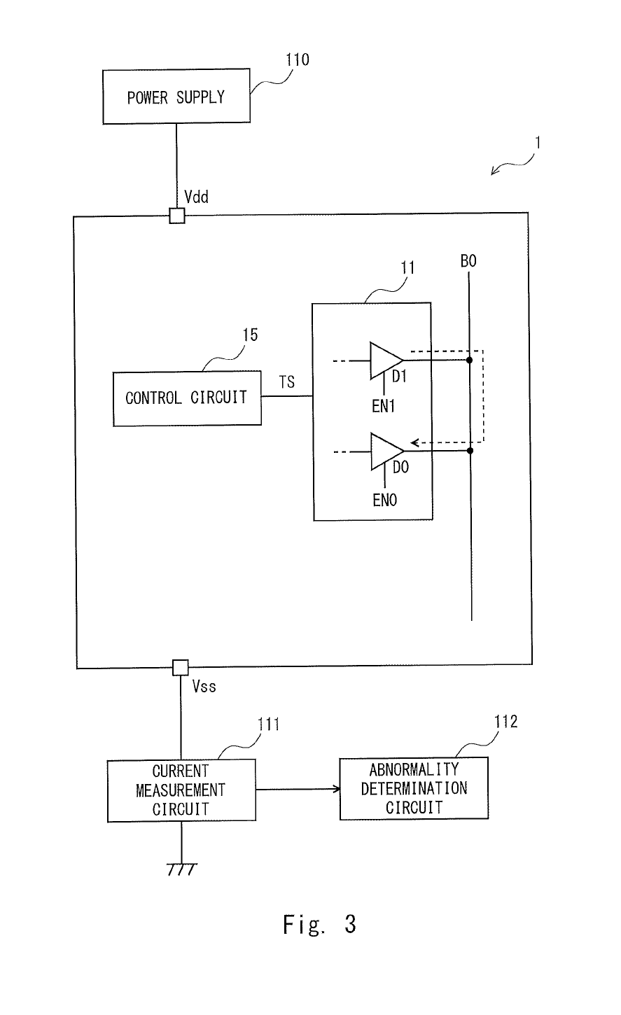

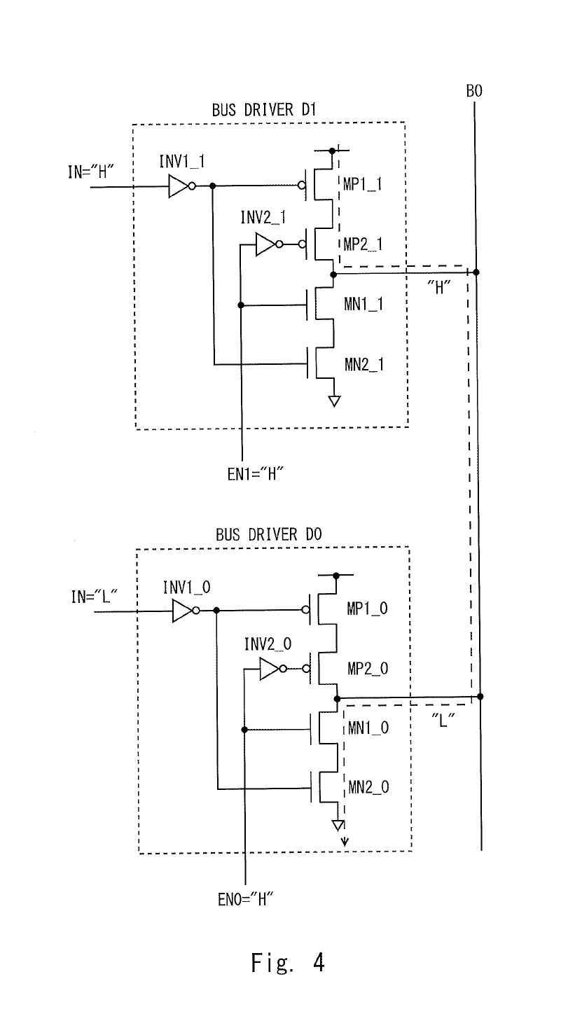

An operation of the semiconductor device according to this embodiment in the test mode will be described with reference to FIGS. 3 and 4. In the test mode, the control circuit 15 controls the bus drivers D0 and D1 so that the bus drivers D0 and D1 supply logic signals different from each other to the bus B0. In the example shown in FIG. 3, the bus driver D1 supplies a high-level logic signal to the bus B0, and the bus driver D0 supplies a low-level logic signal to the bus B0. At this time, a current (a flow-through current) flows from the bus driver D1 to the bus driver D0 via the bus B0.

To be more specific, referring to FIG. 4, when the high-level enable signal EN1 is supplied to the bus driver D1, a P-channel transistor MP2_1 and an N-channel transistor MN1_1 of the bus driver D1 are turned on. In this state, when a high-level signal is supplied to the input terminal IN of the bus driver D1, a low-level signal is supplied to each of the gate of the P-channel transistor MP1_1 and the gate of the N-channel transistor MN2_1. Accordingly, the P-channel transistor MP1_1 is turned on, the N-channel transistor MN2_1 is turned off, and the bus B0 is electrically connected to the power supply line on the high potential side. Thus, a high-level signal is output from the bus driver D1 to the bus B0.

When the high-level enable signal EN0 is supplied to the bus driver D0, a P-channel transistor MP2_0 and an N-channel transistor MN1_0 of the bus driver D0 are turned on. In this state, when a low-level signal is supplied to the input terminal IN of the bus driver D0, a high-level signal is supplied to each of the gate of the P-channel transistor MP1_0 and the gate of the N-channel transistor MN2_0. Accordingly, the P-channel transistor MP1_0 is turned off, the N-channel transistor MN2_0 is turned on, and the bus B0 is electrically connected to the power supply line on the low potential side. Thus, a low-level signal is output from the bus driver D0 to the bus B0.

At this time, a current (a flow-through current) flows through the bus driver D1, the bus B0, and the bus driver D0. Specifically, the flow-through current flows to the power supply line of the bus driver D0 on the low potential side from the power supply line of the bus driver D1 on the high potential side via the P-channel transistors MP1_1 and MP2_1 of the bus driver D1, the bus B0, and the N-channel transistors MN1_0 and MN2_0 of the bus driver D0.

In this embodiment, an abnormality in at least one of the bus B0 and the bus drivers D0 and D1 can be detected based on the amount of the current flowing at this time, i.e., based on the amount of the current flowing when the bus drivers D0 and D1 supply the logic signals different from each other to the bus B0 in the test mode.

Specifically, the amount of the static power supply current of the semiconductor device 1 flowing therethrough when the bus drivers D0 and D1 supply the logic signals different from each other to the bus B0 is measured using the current measurement circuit 111 shown in FIG. 3. When the measured amount of the current is less than or equal to a predetermined reference value, the abnormality determination circuit 112 can determine that at least one of the bus B0 and the bus drivers D0 and D1 is abnormal.

That is, as shown in FIG. 4, when the bus driver D1 supplies the high-level logic signal to the bus B0, and the bus driver D0 supplies the low-level logic signal to the bus B0, the flow-through current flows from the bus driver D1 to the bus driver D0 via the bus B0. However, when an abnormality exists such as a disconnection or a connection failure in the path through which the flow-through current flows, no flow-through current flows or the amount of the flow-through current becomes less than or equal to the predetermined reference value. In this embodiment, an abnormality such as a disconnection or a connection failure in the bus drivers D0 and D1 and the bus B0 can be detected by measuring the amount of the flow-through current.

In the example shown in FIG. 4, it is possible to detect an abnormality such as disconnection or connection failure in the path through which the flow-through current flows, i.e., the path from the power supply line of the bus driver D1 on the high potential side to the power supply line of the bus driver D0 on the low potential side via the P-channel transistors MP1_1 and MP2_1 of the bus driver D1, the bus B0 and the N-channel transistors MN1_0 and MN2_0 of the bus driver D0.

Note that the logic signals supplied to the bus B0 by the bus drivers D0 and D1 may be opposite to those shown in FIGS. 3 and 4. When the logic signals supplied to the bus B0 by the bus drivers D1 and D1 are opposite to those shown in FIGS. 3 and 4, in other words, when the bus driver D0 supplies a high-level logic signal to the bus B0, and the bus driver D1 supplies a low-level logic signal to the bus B0, a current (a flow-through current) flows from the bus driver D0 to the bus driver D1 via the bus B0.

In this case, the flow-through current flows through the path from the power supply line of the bus driver D0 on the high potential side to the power supply line of the bus driver D1 on the low potential side via the P-channel transistors MP1_0 and MP2_0 of the bus driver D0, the bus B0, and the N-channel transistors MN1_1 and MN2_1 of the bus driver D1. This path is partly different from the path shown in FIG. 4. That is, the part of this path inside the bus drivers D0 and D1 is different from the path shown in FIG. 4. Thus, an abnormality such as a disconnection and a connection failure in the paths other than the above path of the bus drivers D0 and D1 can be detected by supplying the logic signals having levels opposite to those shown in FIGS. 3 and 4 from the bus drivers D0 and D1 to the bus B0.

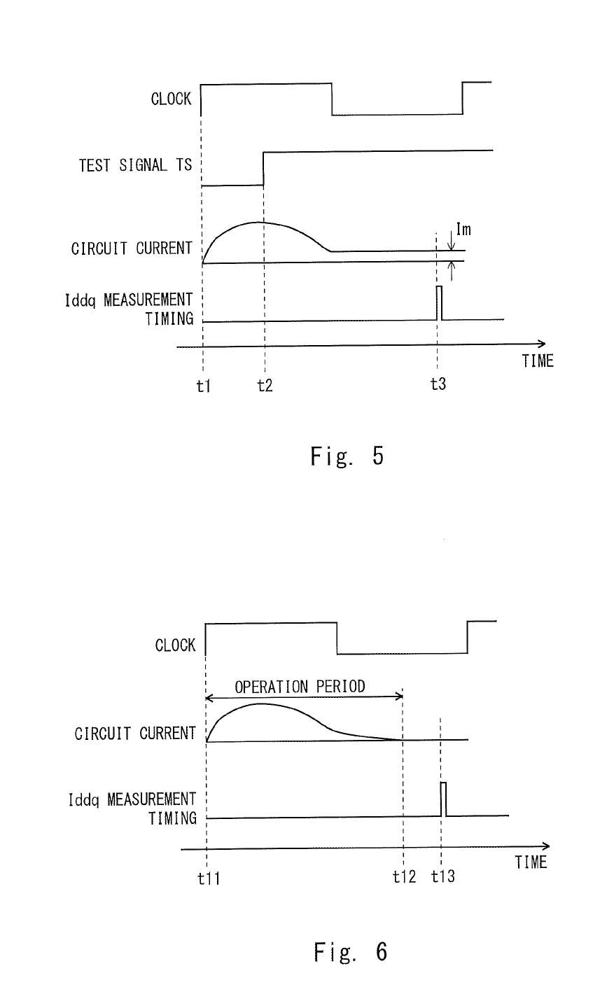

Next, an operation principle of abnormality detection in the semiconductor device according to this embodiment will be described. FIG. 5 is a timing chart for describing the operation of the semiconductor device according to this embodiment. FIG. 6 is a timing chart for describing an operation of a semiconductor device according to a comparative example.

For example, a logic circuit manufactured using the CMOS technology has a property in which a power supply current (Idd) increases at the timing when a logic state of the logic circuit is switched, but only a little power supply current flows when the logic state is fixed. In the comparative example shown in FIG. 6, the circuit starts an operation when the clock rises at a timing t11. After an operation period, a circuit current becomes almost zero at a timing t12 when a logic output of the last stage is decided. In the semiconductor device according to the comparative example, an Iddq measurement timing signal is supplied to a measurement apparatus (a current measurement circuit) at a timing t13, and a circuit current value (i.e., a static power supply current) at this timing t13 is measured. Then, when the measured circuit current value (the static power supply current) is less than or equal to the predetermined set value, the circuit current is determined to be normal.

In contrast, in this embodiment shown in FIG. 5, the circuit starts an operation when the clock rises at a timing t₁. After that, a test signal TS is brought to a high level at a timing t2, and the bus drivers D0 and D1 output logic signals different from each other to the bus B0. Then, after the logic operation is completed, i.e., at a timing after the output of the bus driver is decided, a current (a flow-through current) flows from the bus driver D1 to the bus driver D0 via the bus B0. That is, as shown in FIG. 4, the flow-through current flows from the power supply line of the bus driver D0 on the high potential side to the power supply line of the bus driver D1 on the low potential side via the P-channel transistors MP1_1 and MP2_1 of the bus driver D1, the bus B0, and the N-channel transistors MN1_0 and MN2_0 of the bus driver D0. Therefore, a constant amount of the circuit current flows in the semiconductor device 1.

In this embodiment, as shown in FIG. 5, the Iddq measurement timing signal is supplied to the current measurement circuit 111 (see FIG. 1) at the timing t3, and a circuit current value Im (i.e., the static power supply current) at the timing t3 is measured. Then, it is possible to evaluate whether the semiconductor device 1 is normal based on the measured circuit current value Im (the static power supply current).

That is, assuming that the current value of the static power supply current of the semiconductor device in the normal state is less than or equal to the predetermined reference value, the current exceeding the reference value corresponds to the current flowing through the bus drivers D0 and D1 and the bus B0. Accordingly, when the current value Im measured at the timing t3 in FIG. 5 is greater than the predetermined reference value, the operations of and the connection between the bus drivers D0 and D1 and the bus B0 can be determined to be normal, because the current flows through the path connecting the bus drivers D0 and D1 to the bus B0.

On the other hand, when the current value Im measured at the timing t3 in FIG. 5 is less than or equal to the predetermined reference value, at least one of the bus drivers D0 and D1 and the bus B0 in the above path can be determined to be abnormal due to a logical operation failure or a disconnection, because the current that is supposed to flow through the path connecting the bus drivers D0 and D1 to the bus B0 is not flowing therethrough.

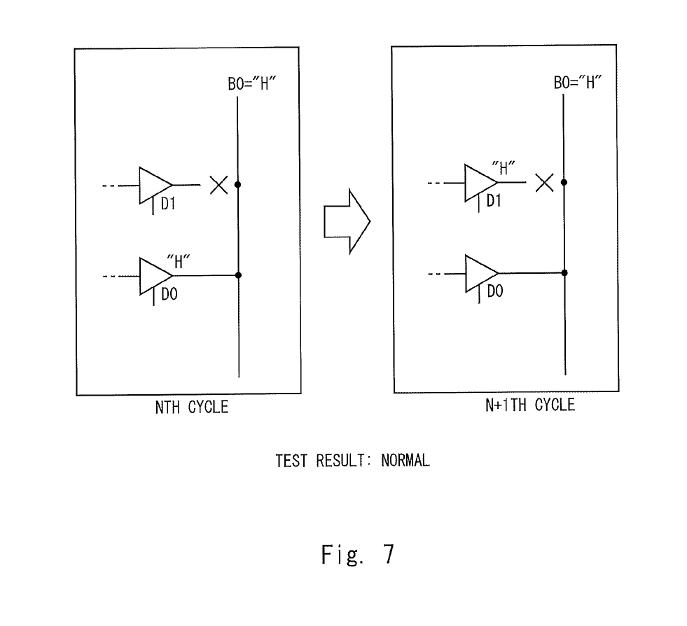

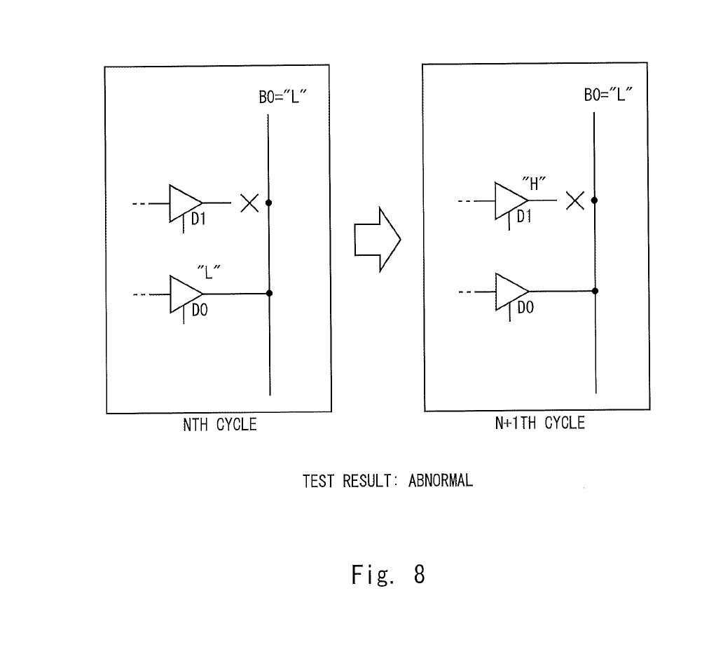

FIGS. 7 and 8 are views for describing an operation test using a logic test of the semiconductor device according to the comparative example. FIGS. 7 and 8 show an operation of detecting an abnormality when a connection failure exists between the bus driver D1 and the bus B0. In the operation test according to the comparative example shown in FIGS. 7 and 8, when the bus driver drives the bus, only one bus driver is in an operating state (the enable signal is at the high level), and the output of the other bus driver is in a high impedance state (the enable signal is at the low level).

As shown in FIG. 7, in the Nth cycle of the operation test, a high-level signal is supplied from the bus driver D0 to the bus B0. Then, the parasitic capacitance of the bus B0 is charged, and the bus B0 is brought to a high level. At this time, a low-level enable signal is supplied to the bus driver D1 (the tri-state buffer), and the output of the bus driver D1 is in a high impedance state.

Next, the bus driver D1 operates in the (N+1)th cycle. Here, when an output value (an expected value) of the bus driver D1 is at the high level, a result will be the same as the result when the bus driver D1 successfully drives the bus B0 to a high level even if a connection failure exists between the bus driver D1 and the bus B0, because the parasitic capacitance charged in the Nth cycle maintains the potential of the bus B0. For this reason, it turns out that a test of the logic level of the bus B0 determines it to be a high level, which is same as the level of the output value (the expected value) of the bus driver D1. Thus, the test result shows normal. That is, in this case, a connection failure between the bus driver D1 and the bus B0 cannot be detected.

Next, an operation test of the semiconductor device according to the comparative example shown in FIG. 8 will be described. As shown in FIG. 8, when a low-level signal is supplied from the bus driver D0 to the bus B0 in the Nth cycle of the operation test, the parasitic capacitance of the bus B0 is discharged, and the bus B0 is brought to a low level. At this time, a low-level enable signal is supplied to the bus driver D1 (the tri-state buffer), and the output of the bus driver D1 is in a high impedance state.

Next, the bus driver D1 operates in the (N+1)th cycle. At this time, when the output value (the expected value) of the bus driver D1 is at the high level, a connection failure exists between the bus driver D1 and the bus B0. Thus, the bus driver D1 cannot charge the parasitic capacitance of the bus B0. In this case, the output value (the expected value) of the bus driver D1 has a different logic level from the logic level of the bus B0, and the test result shows an abnormality.

As described above, in the operation test using the logic test including the bus B0, an evaluation of normal/abnormal from the logical state in a specific step in some cases may not be accurate, because it is affected by the previous operation step. This causes an inconsistency to occur in the results of the operation tests, and the reliability of the operation test to decrease.

Further, for example, when a high resistance component is included between the output of the bus driver D1 and the bus B0, if the operation cycle in the logic test is short, the test shows abnormal, because the parasitic capacitance of the bus B0 cannot be charged. However, when the operation cycle during the logic test is long, the parasitic capacitance of the bus B0 can be charged, and the test shows normal. As described above, in the operation test of the semiconductor device according to the comparative example, the test result differs in some cases depending on the setting of the condition of the logical test.

For this reason, some problems are necessary to expand the conditions of the logic test and to conduct a logic test using means other than the above-described one, resulting in an increase in the time spent on the operation test. In addition, as described above, as the integration of semiconductor devices has progressed in recent years, the operation test of a semiconductor device has tended to become complicated, and the time required for the operation test has tended to become longer. Therefore, a technique to simplify the operation test of the semiconductor device and shorten the time required for the operation test is required.

To this end, in the semiconductor device 1 according to this embodiment, the bus drivers D0 and D1 simultaneously supply the logic signals different from each other to the bus B0 in the test mode. Then, a current (flow-through current) flows through the path connecting the bus drivers D0 and D1 to the bus B0. An abnormality in the bus drivers D0 and D1 and the bus B0 can be detected by measuring this flow-through current.

That is, a resistance value of the path connecting the bus drivers D0 and D1 to the bus B0 can be directly evaluated by measuring the flow-through current flowing through the path connecting the bus drivers D0 and D1 to the bus B0 and evaluating it. This enables a direct evaluation on whether the wiring structure from the bus drivers to the bus is defective or not. The comparative example shown in FIGS. 7 and 8 has a problem that the functional test using the logic test is unstable due to the parasitic capacitance of the bus B0. However, in this embodiment, the resistance value of the path connecting the bus drivers D0 and D1 to the bus B0 is directly evaluated. This avoids such instability of the functional test using the logic test caused by the parasitic capacitance. Further, various condition settings may be made in order to reduce the instability of the functional test using the logical test to thereby reduce the number of times of repeating a similar operation test. Thus, the man−hours required for the operation test can be reduced. This simplifies the operation test of the semiconductor device and shortens the time required for the operation test.

### Second Embodiment

Next, a second embodiment will be described.

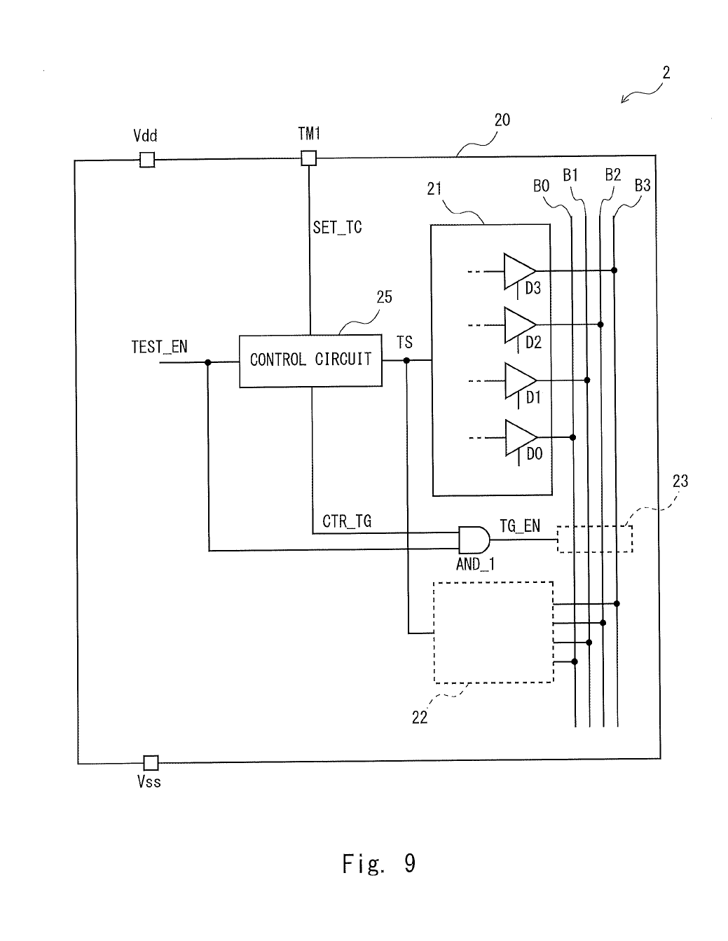

FIG. 9 is a view for describing a semiconductor device according to the second embodiment. The semiconductor device 2 according to the second embodiment differs from the semiconductor device 1 described in the first embodiment in that it has a plurality of buses B0 to B3 and a bus connection circuit 23 capable of connecting the plurality of buses B0 to B3 to each other. As the configuration and operation of the semiconductor device 2 of this embodiment other than the above point are the same as those of the semiconductor device 1 described in the first embodiment, the repeated descriptions will be omitted as appropriate.

As shown in FIG. 9, the semiconductor device 2 according to this embodiment includes at least the plurality of buses B0 to B3, logic modules 21 and 22, the bus connection circuit 23, and a control circuit 25. Note that, in the semiconductor device 2 shown in FIG. 9, only the components necessary for describing this embodiment are described, and descriptions of other commonly known components are omitted. In this embodiment, for example, the semiconductor device 2 is, for example, a logic LSI and a microcomputer manufactured using CMOS technology.

Like the semiconductor device according to the first embodiment, in the semiconductor device 2 according to this embodiment, an abnormality in the semiconductor device 2 is detected by measuring a static power supply current (Iddq) of the semiconductor device 2. In FIG. 9, the descriptions of the power supply 110, the current measurement circuit 111, and the abnormality determination circuit 112 (see FIG. 1) are omitted.

As shown in FIG. 9, in the semiconductor device 2 according to this embodiment, the plurality of logic modules 21 and 22 are connected to the plurality of buses B0 to B3. Each of the logic modules 21 and 22 is configured to be able to transmit and receive data to each other via the plurality of buses B0 to B3. Further, the control circuit 25 supplies a test signal TS to the logic modules 21 and 22 in order to conduct the operation test of the semiconductor device 2. Furthermore, the bus connection circuit 23 is configured to be able to connect the plurality of buses B0 to B3 to each other when the operation test is conducted on the semiconductor device 2.

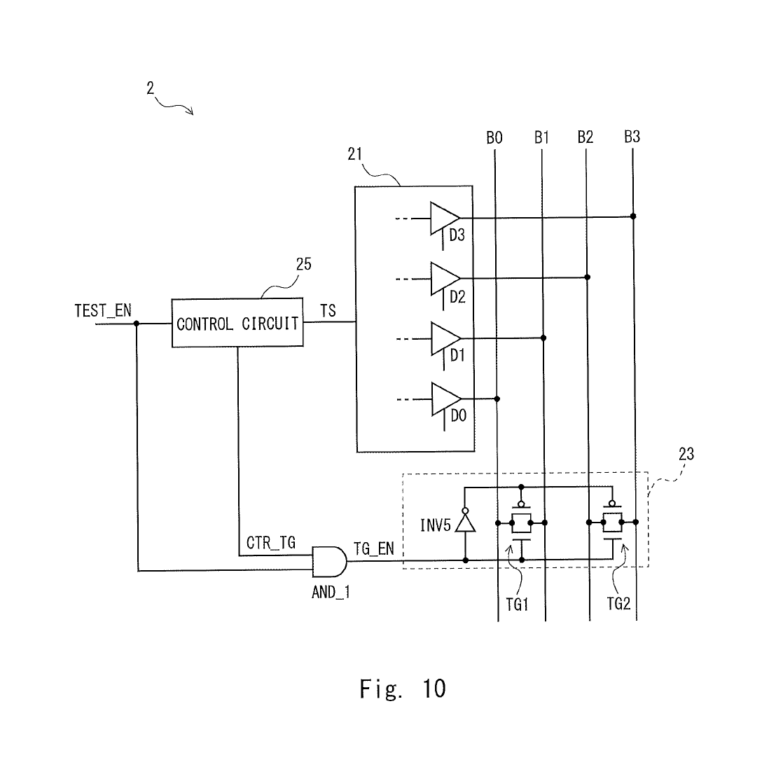

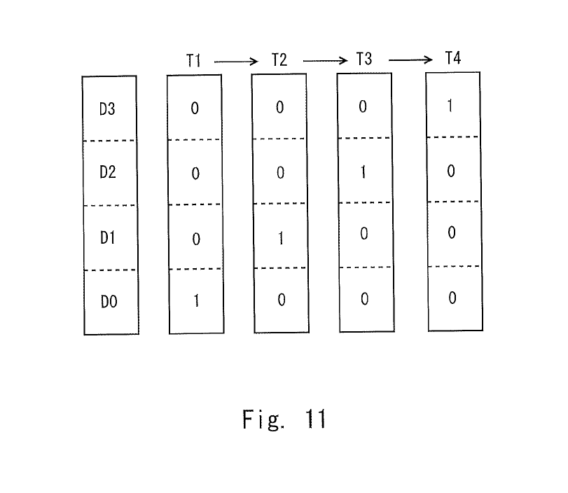

FIG. 10 is a view for describing the details of the semiconductor device according to this embodiment. Although the description of the logic module 22 will be omitted here for convenience, the configuration and operation of the logic module 22 are the same as those of the logic module 21.

As shown in FIG. 10, the logic module 21 includes bus drivers D0 to D3 that drive the buses B0 to B3, respectively. Specifically, output terminals of the bus drivers D0 to D3 are connected to the buses B0 to B3, respectively, and output the logic signals inside the logic module 21 to the buses B0 to B3, respectively. That is, the bus drivers D0 to D3 function as output bus drivers for outputting the logic signals inside the logic module 21 to the buses B0 to B3, respectively. As in the case described in the first embodiment, each of the bus drivers D0 to D3 may be composed of a tri-state buffer. Note that descriptions of other circuit elements (logic circuits, drivers for inputting signals from the bus, etc.) included in the logic module 21 are omitted.

The bus connection circuit 23 is configured to be able to connect the plurality of buses B0 to B3 to each other when the operation test is conducted on the semiconductor device 2. Specifically, the bus connection circuit 23 includes a switching element TG1 provided between the bus B0 and the bus B1, and a switching element TG2 provided between the bus B2 and the bus B3. When the operation test is conducted on the semiconductor device 2 (i.e., in the test mode), the switching element TG1 connects the buses B0 and B1 to each other, and the switching element TG2 connects the buses B2 and B3 to each other.

Each of the switching elements TG1 and TG2 may be composed using, for example, a transfer gate. In FIG. 10, a CMOS transfer gate using both an N-channel transistor and a P-channel transistor is shown as an example. However, in this embodiment, other elements may be used as the switching elements TG1 and TG2.

The gates of the N-channel transistors constituting the switching elements TG1 and TG2 are connected to an output of a logical conjunction AND_1. The gates of the P-channel transistors constituting the switching elements TG1 and TG2 are connected to the output of the logical conjunction AND_1 via the inverter INV5. A control signal CTR_TG for controlling the switching elements TG1 and TG2 is supplied from the control circuit 25 to one input of the logical conjunction AND_1. A test enable signal TEST_EN is supplied to the other inputs of the logical conjunction AND_1.

When the operation test is conducted on the semiconductor device 2, the test enable signal TEST_EN is brought to a high level. In this state, when the high-level control signal CTR_TG is supplied from the control circuit 25, the logical conjunction AND_1 outputs a high-level TG_EN signal (a transfer gate enable signal). In this case, a high-level signal is supplied to the gates of the N-channel transistors constituting the switching elements TG1 and TG2, and a low-level signal is supplied to the gates of the P-channel transistors constituting the switching elements TG1 and TG2. Thus, the switching elements TG1 and TG2 are turned on.

On the other hand, when the control signal CTR_TG output from the control circuit 25 is at the low level even when the test enable signal TEST_EN is at the high level, the switching elements TG1 and TG2 are turned off. That is, when the test enable signal TEST_EN is at the high level, the control circuit 25 can control the switching elements TG1 and TG2 to be turned on or off.

When the operation test is conducted, the control circuit 25 controls the bus drivers D0 to D3 by supplying the test signal TS to the logic module 21. As shown in FIG. 9, setting information SET_TC of the operation test is supplied to the control circuit 25 via a test terminal TM1. The test enable signal TEST_EN is supplied to the control circuit 25.

Next, an operation of the semiconductor device 2 according to this embodiment will be described. In the semiconductor device 2 shown in FIG. 10, when the operation test is conducted, the test enable signal TEST_EN is brought to a high level. The test enable signal TEST_EN may be supplied from the outside via an external terminal of the semiconductor device 2 or may be generated by an internal circuit of the semiconductor device 2.

When the high-level test enable signal TEST_EN is supplied, the control circuit 25 makes the control signal CTR_TG transition from the low level to the high level. Then, the high-level control signal CTR_TG and the high-level test enable signal TEST_EN are supplied to the input of the logical conjunction AND_1, so that the high-level TG_EN signal is output from the logical conjunction AND_1. Then, the switching element TG1 is turned on, and the bus B0 is connected to the bus B1. Further, the switching element TG2 is turned on, and the bus B2 is connected to the bus B3.

Further, when the high-level test enable signal TEST_EN is supplied, the control circuit 25 supplies the test signal TS to the logic module 21 so that the bus drivers D0 to D3 of the logic module 21 operate with a predetermined test pattern.

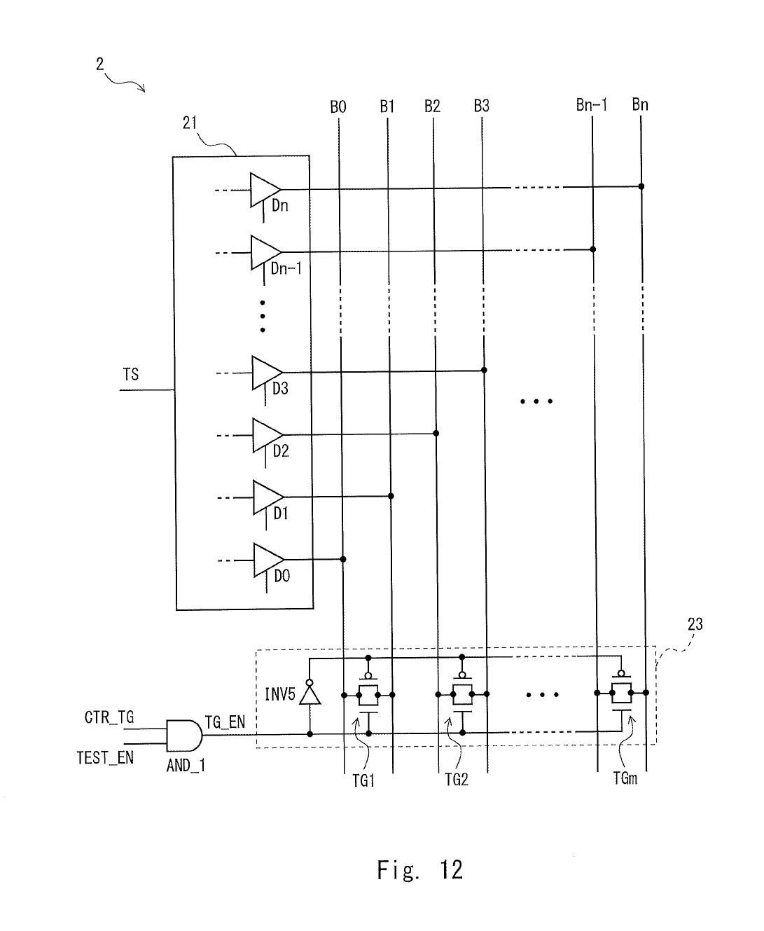

FIG. 11 is a view showing an example of a test pattern of the semiconductor device according to this embodiment. Such a test pattern can be written in the control circuit 25 by, for example, supplying the setting information SET_TC of the operation test from the outside via a test terminal TM1 (see FIG. 9). In the test pattern shown in FIG. 11, “1” indicates a high-level logic signal and “0” indicates a low-level logic signal.

As shown in FIG. 11, in the test patterns T1 and T2, the control circuit 25 controls the bus drivers D0 and D1 so that the bus drivers D0 and D1 supply logic signals different from each other to the buses B0 and B1, respectively. At this time, the bus drivers D2 and D3 supply the same logic signals to the buses B2 and B3, respectively. In FIG. 11, the bus drivers D2 and D3 supply low-level logic signals to the buses B2 and B3, respectively. However, in this embodiment, the logic signals supplied by the bus drivers D2 and D3 to the buses B2 and B3 may be the same. Thus, the bus drivers D2 and D3 may supply high-level logic signals to the buses B2 and B3, respectively.

In the test patterns T3 and T4, the control circuit 25 controls the bus drivers D2 and D3 so that they supply the logic signals different from each other to buses B2 and B3, respectively. At this time, the bus drivers D0 and D1 supply the same logic signal to the buses B0 and B1, respectively. In FIG. 11, the bus drivers D0 and D1 supply low-level logic signals to the buses B0 and B1, respectively. However, in this embodiment, the logic signals supplied by the bus drivers D0 and D1 to the buses B0 and B1 may be the same. Thus, the bus drivers D0 and D1 may supply the high-level logic signals to the buses B0 and B1, respectively.

Specifically, in the test pattern T1, the bus driver D0 supplies a high-level logic signal to the bus B0, and the bus driver D1 supplies a low-level logic signal to the bus B1. Then, a current (a flow-through current) flows from the bus driver D0 to the bus driver D1 via the bus B0, the switching element TG1, and the bus B1. In this embodiment, when the amount of the static power supply current flowing at this time is less than a previously-set expected value, an abnormality in at least one of the buses B0 and B1 and the bus drivers D0 and D1 can be detected. Note that the method of detecting an abnormality using the amount of the flow-through current is the same as the method described in the first embodiment. Thus, repeated descriptions are omitted.

In the test pattern T1, the bus drivers D2 and D3 supply low-level logic signals to the buses B2 and B3, respectively. In this case, no flow-through current flows through the path including the bus drivers D2 and D3 and the buses B2 and B3. That is, in this embodiment, by setting the number of paths through which the flow-through current flows, it is possible to identify a path exhibiting an abnormality.

Next, in the test pattern T2, the bus driver D0 supplies a low-level logic signal to the bus B0, and the bus driver D1 supplies a high-level logic signal to the bus B1. Then, a flow-through current flows from the bus driver D1 to the bus driver D0 via the bus B1, the switching element TG1, and the bus B0. The path through which the current flows is opposite to the path in the test pattern T1.

Then, an abnormality in at least one of the buses B0 and B1 and the bus drivers D0 and D1 can be detected based on the amount of the flow-through current flowing in the test pattern T2. Note that in the test pattern T2, the bus drivers D2 and D3 supply low-level logic signals to the buses B2 and B3, respectively. In this case, no flow-through current flows through the path including the bus drivers D2 and D3 and the buses B2 and B3.

In this embodiment, the amount of the flow-through current in the test pattern T1 may be compared with the amount of the flow-through current in the test pattern T2 to detect an abnormality in at least one of the buses B0 and B1 and the bus drivers D0 and D1.

Next, in the test pattern T3, the bus driver D2 supplies the high-level logic signal to the bus B2, and the bus driver D3 supplies the low-level logic signal to the bus B3. Then, a flow-through current flows from the bus driver D2 to the bus driver D3 via the bus B2, the switching element TG2, and the bus B3.

Then, an abnormality in at least one of the buses B2 and B3 and the bus drivers D2 and D3 can be detected based on the amount of the flow-through current flowing in the test pattern T3. In the test pattern T3, the bus drivers D0 and D1 supply low-level logic signals to the buses B0 and B1, respectively. In this case, no flow-through current flows through the path including the bus drivers D0 and D1 and the buses B0 and B1.

Next, in the test pattern T4, the bus driver D2 supplies a low-level logic signal to the bus B2, and the bus driver D3 supplies a high-level logic signal to the bus B3. Then, a flow-through current flows from the bus driver D3 to the bus driver D2 via the bus B3, the switching element TG2, and the bus B2. The path through which the flow-through current flows is opposite to the path in the test pattern T3.

Then, an abnormality in at least one of the buses B2 and B3 and the bus drivers D2 and D3 can be detected based on the amount of the flow-through current flowing in the test pattern T4. In the test pattern T4, the bus drivers D0 and D1 supply low-level logic signals to the buses B0 and B1, respectively. In this case, no flow-through current flows through the path including the bus drivers D0 and D1 and the buses B0 and B1.

In this embodiment, the amount of the flow-through current in the test pattern T3 may be compared with the amount of the flow-through current in the test pattern T4 to detect an abnormality in at least one of the buses B2 and B3 and the bus drivers D2 and D3.

After the operation test of the semiconductor device 2 is completed, the test enable signal TEST_EN is brought to a low level. Then, the output of the logical conjunction AND_1 is brought to a low level, and the switching elements TG1 and TG2 are turned off. This disconnects the connections of the respective buses B0 to B3, and a normal operation becomes possible.

FIG. 12 shows a configuration in which the semiconductor device 2 according to this embodiment includes n+1 buses B0 to Bn and n+1 bus drivers D0 to Dn. In this case, m switching elements TG1 to TGm connecting the respective buses B0 to Bn are provided. Each of the switching elements TG1 to TGm connects the bus Bn−1 to the bus Bn (n is an odd number of one or greater).

In the semiconductor device 2 according to this embodiment, a resistance value of the path connecting the bus driver to the bus is directly evaluated. Thus, the setting conditions of the operation test (logic test) can be reduced, and the man−hours required for the operation test can be reduced. This simplifies the operation test of the semiconductor device and shortens the time required for the operation test.

Further, in the semiconductor device 2 according to this embodiment, in the test mode, the respective buses are connected to each other using switching elements, and the bus drivers connected to the respective buses supply logic signals different from each other to the respective buses. Since the bus can be tested in units of two bits, the time required for the operation test can be shortened.

### Third Embodiment

Next, a third embodiment will be described.

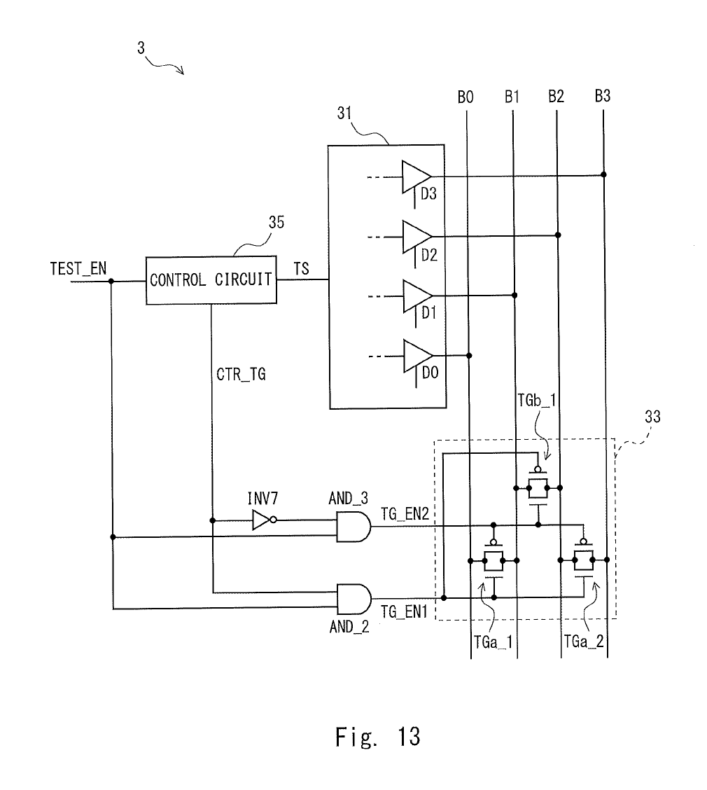

FIG. 13 is a view for describing the semiconductor device according to the third embodiment. The semiconductor device 3 according to the third embodiment differs from the semiconductor device 2 described in the second embodiment in that it includes a switching element TGb_1 that connects the bus B1 to the bus B2. As the configuration and operation of the semiconductor device 3 of this embodiment other than the above point are the same as those of the semiconductor devices 1 and 2 described in the first and second embodiments, respectively, the repeated descriptions will be omitted as appropriate.

As shown in FIG. 13, the semiconductor device 3 according to this embodiment includes at least a plurality of buses B0 to B3, a logic module 31, a bus connection circuit 33, and a control circuit 35. Note that, in the semiconductor device 3 shown in FIG. 13, only the components necessary for describing this embodiment are described, and descriptions of other commonly known components are omitted. In this embodiment, for example, the semiconductor device 3 is, for example, a logic LSI and a microcomputer manufactured using CMOS technology.

Like the semiconductor devices according to the first and second embodiments, in the semiconductor device 3 according to this embodiment, an abnormality in the semiconductor device 3 is detected by measuring the static power supply current (Iddq) of the semiconductor device 3. In FIG. 13, the descriptions of the power supply 110, the current measurement circuit 111, and the abnormality determination circuit 112 (see FIG. 1) are omitted.

As shown in FIG. 13, the logic module 31 includes bus drivers D0 to D3 for driving the buses B0 to B3, respectively. Specifically, the output terminals of the bus drivers D0 to D3 are connected to the buses B0 to B3, respectively, and output the logic signals inside the logic module 31 to the buses B0 to B3, respectively. That is, the bus drivers D0 to D3 function as output bus drivers for outputting the logic signals in the logic module 31 to the buses B0 to B3. As in the case described in the first and second embodiments, the bus drivers D0 to D3 may be composed of tri-state buffers. Note that descriptions of other circuit elements (logic circuits, drivers for inputting signals from the bus, etc.) included in the logic module 31 are omitted.

The bus connection circuit 33 is configured to be able to connect the plurality of buses B0 to B3 to each other when the operation test is conducted on the semiconductor device 3. Specifically, the bus connection circuit 33 includes a switching element TGa_1 provided between the bus B0 and the bus B1 and a switching element TGa_2 provided between the bus B2 and the bus B3. At a first timing of the test mode of the semiconductor device 3, the switching element TGa_1 connects the buses B0 and B1 to each other, and the switching element TGa_2 connects the buses B2 and B3 to each other.

The bus connection circuit 33 further includes a switching element TGb_1 provided between the bus B1 and the bus B2. At a second timing of the semiconductor device 3 in the test mode, the switching element TGb_1 connects the buses B1 and B2 to each other. Here, the first timing and the second timing are different timings. In other words, the first timing and the second timing have a complementary relationship to each other, and the switching elements TGa_1 and TGa_2 and the switching element TGb_1 are alternately turned on and off.

The switching elements TGa_1, TGa_2, and TGb_1 can be composed using, for example, transfer gates. In FIG. 13, a CMOS transfer gate using both an N-channel transistor and a P-channel transistor is shown as an example. However, other elements may be used as the switching elements TGa_1, TGa_2, TGb_1 in this embodiment.

The gates of the N-channel transistors constituting the switching elements TGa_1 and TGa_2 are connected to an output of an AND_2. The gates of the P-channel transistors constituting the switching elements TGa_1 and TGa_2 are connected to an output of an AND_3.

Further, the gate of the P-channel transistor constituting the switching element TGb_1 is connected to the output of the logical conjunction AND_2. Further, the gate of the N-channel transistor constituting the switching element TGb_1 is connected to the output of the logical conjunction AND_3.

The control signal CTR_TG is supplied from the control circuit 25 to one input of the logical conjunction AND_2. Further, the control signal CTR_TG is supplied from the control circuit 25 to one input of the logical conjunction AND_3 via an inverter INV7. The test enable signal TEST_EN is supplied to the other input of each of the logical conjunctions AND_2 and AND_3.

When the operation test is conducted on the semiconductor device 3, the test enable signal TEST_EN is brought to a high level. In this state, when the control circuit 25 outputs the high-level control signal CTR_TG, a high-level signal is supplied to the logical conjunction AND_2, and a low-level signal is supplied to the logical conjunction AND_3. In this case, a high-level TG_EN1 signal (a transfer gate enable signal) is output from the logical conjunction AND_2, and a low-level TG_EN2 signal is output from the logical conjunction AND_3.

In this case, the high-level signal is supplied to the gates of the N-channel transistors constituting the switching elements TGa_1 and TGa_2, and the low-level signal is supplied to the gates of the P-channel transistors constituting the switching elements TGa_1 and TGa_2. Thus, the elements TGa_1 and TGa_2 are turned on. On the other hand, the low-level signal is supplied to the gate of the N-channel transistor constituting the switching element TGb_1, and the high-level signal is supplied to the gate of the P-channel transistor constituting the switching element TGb_1. Thus, the switching element TGb_1 is turned off.

When the control circuit 25 outputs the low-level control signal CTR_TG while the test enable signal TEST_EN is at the high level, a low-level signal is supplied to the logical conjunction AND_2, and a high-level signal is supplied to the logical conjunction AND_3. In this case, the low-level TG_EN1 signal is output from the logical conjunction AND_2, and the high-level TG_EN2 signal is output from the logical conjunction AND_3.

In this case, the low-level signal is supplied to the gates of the N-channel transistors constituting the switching elements TGa_1 and TGa_2, and the high-level signal is supplied to the gates of the P-channel transistors constituting the switching elements TGa_1 and TGa_2. Thus, the elements TGa_1 and TGa_2 are turned off. On the other hand, the high-level signal is supplied to the gate of the N-channel transistor constituting the switching element TGb_1, and the low-level signal is supplied to the gate of the P-channel transistor constituting the switching element TGb_1. Thus, the switching element TGb_1 is turned on.

Switching the levels of the control signal CTR_TG supplied from the control circuit 35 in this manner enables the switching elements TGa_1 and TGa_2 and the switching element TGb_1 to be alternately (i.e., in a complementary manner) turned on and off.

When the operation test is conducted, the control circuit 35 controls the bus drivers D0 to D3 by supplying the test signal TS to the logic module 31. Further, the test enable signal TEST_EN is supplied to the control circuit 35.

Next, an operation of the semiconductor device 3 according to this embodiment will be described. When the operation test is conducted on the semiconductor device 3, the test enable signal TEST_EN is brought to a high level. The test enable signal TEST_EN may be supplied from the outside via an external terminal (see FIG. 9) of the semiconductor device 3, or may be generated by an internal circuit of the semiconductor device 3.

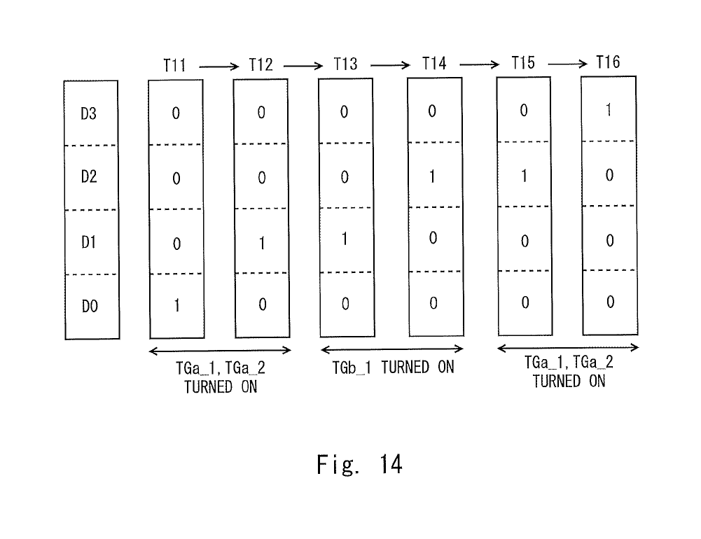

FIG. 14 is a view showing an example of a test pattern of the semiconductor device according to this embodiment. In this embodiment, as shown in the test pattern shown in FIG. 14, the control circuit 35 controls the levels of the logic signals of the respective bus drivers D0 to D3 and also controls the timings of turning on and off the switching elements TGa_1, TGa_2, and TGb_1.

In the test patterns T11 and T12, the switching elements TGa_1 and TGa_2 are turned on, and the switching element TGb_1 is turned off. Then, the bus B0 is connected to the bus B1 using the switching element TGa_1, and the bus B2 is connected to the bus B3 using the switching element TGa_2.

In the test pattern T11, the bus driver D0 supplies a high-level logic signal to the bus B0, and the bus driver D1 supplies a low-level logic signal to the bus B1. Then, a current (a flow-through current) flows from the bus driver D0 to the bus driver D1 via the bus B0, the switching element TGa_1, and the bus B1. In this embodiment, when the amount of the static power supply current flowing at this time is less than a previously-set expected value, an abnormality in at least one of the buses B0 and B1 and the bus drivers D0 and D1 can be detected. Note that the method of detecting an abnormality using the amount of the flow-through current is the same as the method described in the first embodiment. Thus, repeated descriptions are omitted.

In the test pattern T11, the bus drivers D2 and D3 supply low-level logic signals to the buses B2 and B3, respectively. In this case, no flow-through current flows through the path including the bus drivers D2 and D3 and the buses B2 and B3. That is, in this embodiment, by setting the number of paths through which the flow-through current flows, it is possible to identify a path exhibiting an abnormality.

Next, in the test pattern T12, the bus driver D0 supplies a low-level logic signal to the bus B0, and the bus driver D1 supplies a high-level logic signal to the bus B1. Then, a flow-through current flows from the bus driver D1 to the bus driver D0 via the bus B1, the switching element TGa_1, and the bus B0. The path through which the flow-through current flows is opposite to the path in the test pattern T11.

Then, an abnormality in at least one of the buses B0 and B1 and the bus drivers D0 and D1 can be detected based on the amount of the flow-through current flowing in the test pattern T12. In the test pattern T12, the bus drivers D2 and D3 supply low-level logic signals to the buses B2 and B3, respectively. In this case, no flow-through current flows through the path including the bus drivers D2 and D3 and the buses B2 and B3.

In the test patterns T13 and T14, the switching elements TGa_1 and TGa_2 are turned off, and the switching element TGb_1 is turned on. Then, the bus B1 is connected to the bus B2 using the switching element TGb_1.

Further, in the test pattern T13, the bus driver D1 supplies a high-level logic signal to the bus B1, and the bus driver D2 supplies a low-level logic signal to the bus B2. Then, a current (a flow-through current) flows from the bus driver D1 to the bus driver D2 via the bus B1, the switching element TGb_1, and the bus B2. In this embodiment, an abnormality in at least one of the buses B1 and B2 and the bus drivers D1 and D2 can be detected based on the amount of the current flowing at this time.

In the test pattern T13, the bus drivers D0 and D3 supply low-level logic signals to the buses B0 and B3, respectively. In this case, no flow-through current flows through the path including the bus drivers D0 and D3 and the buses B0 and B3.

Next, in the test pattern T14, the bus driver D1 supplies a low-level logic signal to the bus B1, and the bus driver D2 supplies a high-level logic signal to the bus B2. Then, a flow-through current flows from the bus driver D2 to the bus driver D1 via the bus B2, the switching element TGb_1, and the bus B1. The path through which the flow-through current flows is opposite to the path in the test pattern T13.

Then, an abnormality in at least one of the buses B1 and B2 and the bus drivers D1 and D2 can be detected based on the amount of the flow-through current flowing in the test pattern T14. In the test pattern T14, the bus drivers D0 and D3 supply low-level logic signals to the buses B0 and B3, respectively. In this case, no flow-through current flows through the path including the bus drivers D0 and D3 and the buses B0 and B3.

In the test patterns T15 and T16, the switching elements TGa_1 and TGa_2 are turned on again, and the switching element TGb_1 is turned off. Then, the bus B0 is connected to the bus B1 using the switching element TGa_1, and the bus B2 is connected to the bus B3 using the switching element TGa_2.

In the test pattern T15, the bus driver D2 supplies a high-level logic signal to the bus B2, and the bus driver D3 supplies a low-level logic signal to the bus B3. Then, a current (a flow-through current) flows from the bus driver D2 to the bus driver D3 via the bus B2, the switching element TGa_2, and the bus B3. In this embodiment, an abnormality in at least one of the buses B2 and B3 and the bus drivers D2 and D3 can be detected based on the amount of the current flowing at this time.

In the test pattern T15, the bus drivers D0 and D1 supply low-level logic signals to the buses B0 and B1, respectively. In this case, no flow-through current flows through the path including the bus drivers D0 and D1 and the buses B0 and B1.

Next, in the test pattern T16, the bus driver D2 supplies a low-level logic signal to the bus B2, and the bus driver D3 supplies a high-level logic signal to the bus B3. Then, a flow-through current flows from the bus driver D3 to the bus driver D2 via the bus B3, the switching element TGa_2, and the bus B2. The path through which the flow-through current flows is opposite to the path in the test pattern T15.

Then, an abnormality in at least one of the buses B2 and B3 and the bus drivers D2 and D3 can be detected based on the amount of the flow-through current flowing in the test pattern T16. In the test pattern T16, the bus drivers D0 and D1 supply low-level logic signals to the buses B0 and B1, respectively. In this case, no flow-through current flows through the path including the bus drivers D0 and D1 and the buses B0 and B1.

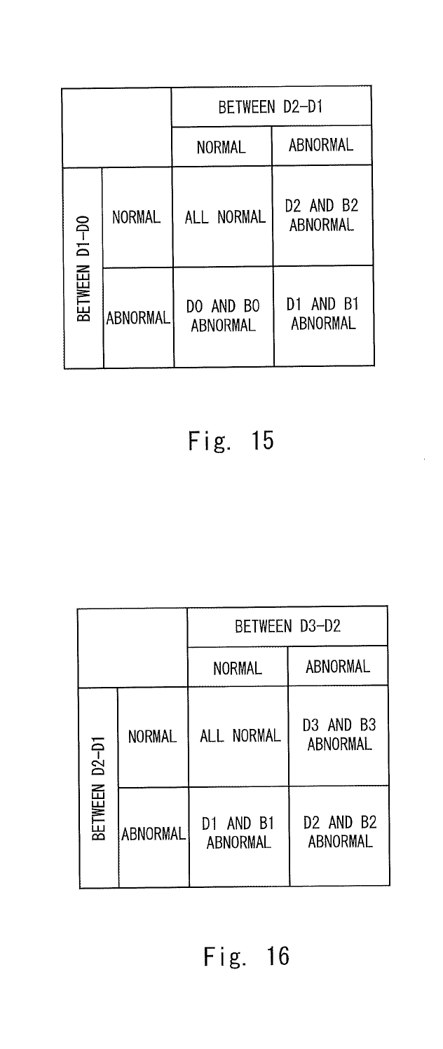

FIGS. 15 and 16 are tables for describing determination results of the operation tests on the semiconductor device according to this embodiment. In this embodiment, an abnormal part can be identified using the above-described results of the operation test.

For example, as shown in FIG. 15, when the operation test between the bus drivers D1 and D0 (the test patterns T11 and T12) shows an abnormality, and the operation test between the bus drivers D2 and D1 (the test patterns T13 and T14) shows an abnormality, the path including the bus driver D1 and the bus B1 is determined to be abnormal. In other words, in this case, the path including the bus driver D1 and the bus B1, which has been evaluated commonly between the operation test between the bus drivers D1 and D0 and the operation test between the bus drivers D2 and D1, is determined to be abnormal.

Further, when the operation test between the bus drivers D1 and D0 (the test patterns T11 and T12) shows normal, and the operation test between the bus drivers D2 and D1 (the test patterns T13 and T14) shows an abnormality, the path including the bus driver D2 and the bus B2 is determined to be abnormal. That is, in this case, the operation test between the bus drivers D1 and D0 shows normal, and thus the path including the remaining bus drivers D2 and the bus B2 among the bus drivers D0 to D2 is determined to be abnormal.

Further, when the operation test (the test patterns T11 and T12) between the bus driver D1 and the bus driver D0 is determined to be abnormal, and the operation test (the test patterns T13 and T14) between the bus driver D2 and the bus driver D1 shows normal, the path including the bus driver D0 and the bus B0 is determined to be abnormal. That is, in this case, as the operation test between the bus drivers D2 and D1 shows normal, the path including the remaining bus drivers D0 and B0 among the bus drivers D0 to D2 is determined to be abnormal.

Further, when the operation test between the bus drivers D1 and D0 (the test patterns T11 and T12) shows normal, and the operation test (test patterns T13 and T14) between the bus driver D2 and the bus driver D1 shows normal, the bus drivers D0 to D2 are determined to be normal.

As shown in FIG. 16, when the operation test between the bus driver D2 and D1 (the test pattern T13 and T14) shows an abnormality, and the operation test between the bus drivers D3 and D2 (the test patterns T15 and T16) shows an abnormality, the path including the bus driver D2 and the bus B2 is determined to be abnormal. In other words, in this case, the path including the bus driver D2 and the bus B2, which has been evaluated commonly between the operation test between the bus drivers D2 and D1 and the operation test between the bus drivers D3 and D2, is determined to be abnormal.

Further, when the operation test between the bus drivers D2 and D1 (the test pattern T13 and T14) shows normal, and the operation test between the bus drivers D3 and D2 (the test patterns T15 and T16) shows an abnormality, the path including the bus driver D3 and the bus B3 is determined to be abnormal. That is, in this case, the operation test between the bus drivers D2 and D1 shows normal, and thus the path including the remaining bus drivers D3 and the bus B3 among the bus drivers D1 to D3 is determined to be abnormal.

Further, when the operation test between the bus drivers D2 and D1 (the test pattern T13 and T14) shows an abnormality, and the operation test between the bus drivers D3 and D2 (the test pattern T15 and T16) shows normal, the path including the bus driver D1 and the bus B1 is determined to be abnormal. That is, in this case, the operation test between the bus drivers D3 and D2 shows normal, and thus the path including the remaining bus drivers D1 and the bus B1 among the bus drivers D1 to D3 is determined to be abnormal.

Further, when the operation test between the bus drivers D2 and D1 (the test pattern T13 and T14) shows normal, and the operation test between the bus drivers D3 and D2 (the test pattern T15 and T16) shows normal, the bus drivers D1 to D3 are determined to be normal.

After the operation test of the semiconductor device 3 is completed, the test enable signal TEST_EN is brought to a low level. Then, the outputs of the logical conjunctions AND_2 and AND_3 are brought to low levels, and the switching elements TGa_1, TGa_2, and TGb_1 are turned off. This disconnects the connections of the respective buses B0 to B3, and a normal operation becomes possible.

As shown in FIG. 10, in the semiconductor device 2 according to the second embodiment, no switching element is provided between the buses B1 and B2. Thus, for example, even when the operation test between the bus drivers D1 and D0 shows an abnormality, it has not been possible to determine whether the bus driver D1 or the bus driver D0 is abnormal.

On the other hand, in the semiconductor device 3 according to this embodiment, as shown in FIG. 13, the switching element TGb_1 is provided between the buses B1 and B2, and the operation test is conducted on the path between the bus drivers D2 and D1. That is, the operation test is also conducted on the path between the bus drivers D2 and D1, which is a path adjacent to the path between the bus drivers D1 and D0. Therefore, the operation test can be conducted on the path between the bus drivers D1 and D0 and also on the path between the bus drivers D2 and D1. This enables an abnormal part of the bus drivers and the buses to be identified.

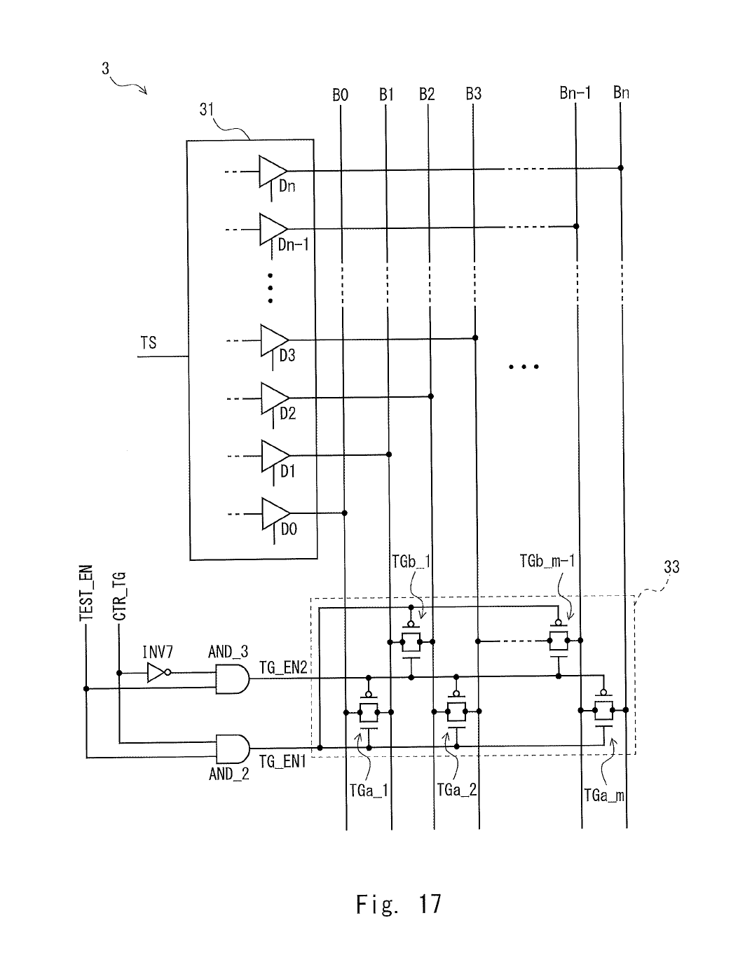

FIG. 17 shows a configuration in which the semiconductor device 3 according to this embodiment includes n+1 buses B0 to Bn and n+1 bus drivers D0 to Dn. In this embodiment, switching elements TGa_1 to TGa_m connecting the bus Ba−1 to the bus Ba (a is an odd number greater than or equal to one and less than or equal to n) are provided. Switching elements TGb_1 to TGb_m−1 for connecting the bus Bb−1 to the bus Bb (b is an even number greater than or equal to two and less than or equal to n−1) are provided. The switching elements TGa_1 to TGa_m and switching elements TGb_1 to TGb_m−1 are alternately turned on and off during the operation test (test mode).

The operation of the semiconductor device 3 according to this embodiment will be described in general terms. When the operation test is conducted on the three bus drivers Dn−2, Dn−1, and Dn connected to the 3-bit buses Bn−2, Bn−1, and Bn, an abnormal part can be identified as follows.

When an abnormality exists in the path between the bus drivers Dn−2 and Dn−1, and an abnormality exixts in the path between the bus drivers Dn−1 and Dn, the path including the bus driver Dn−1 and the bus Bn−1 can be determined to be abnormal.

When the path between the bus drivers Dn−2 and Dn 1 is normal, and an abnormality exixts in the path between the bus drivers Dn−1 and Dn, the path including the bus driver Dn and the bus Bn can be determined to be abnormal.

When an abnormality exixts in the path between the bus drivers Dn−2 and Dn−1, and the path between the bus drivers Dn−1 and Dn is normal, the path including the bus driver Dn−2 and the bus Bn−2 can be determined to be abnormal.

As described above, in the semiconductor device 3 according to this embodiment, an abnormal part can be identified in units of 1 bit.

### Fourth Embodiment

Next, a fourth embodiment will be described.

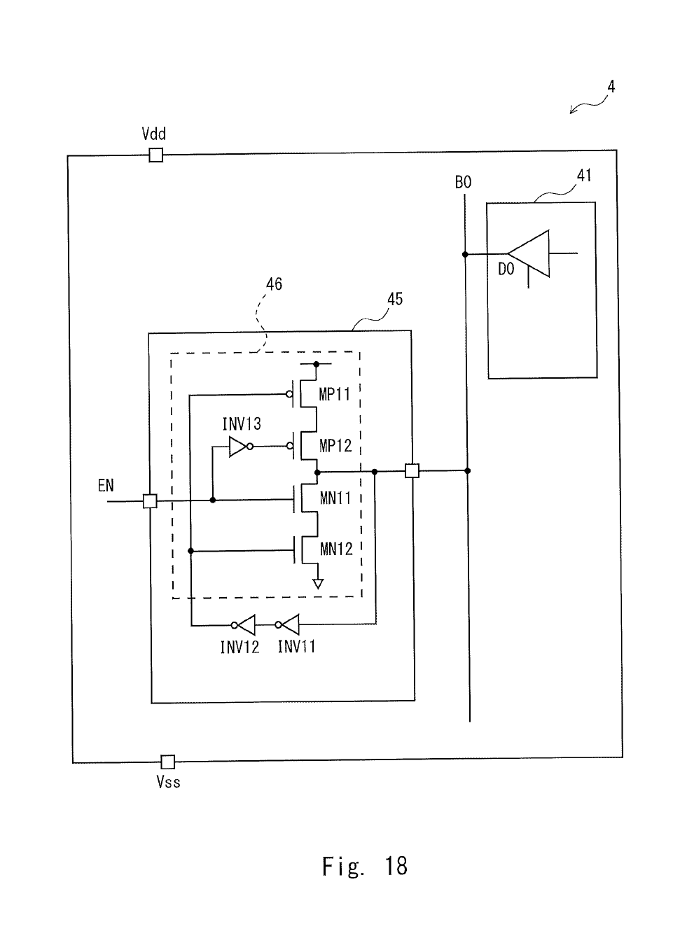

FIG. 18 is a view for describing a semiconductor device according to the fourth embodiment. The semiconductor device 4 according to the fourth embodiment differs from the semiconductor device 1 described in the first embodiment in that it includes a verification circuit 45. That is, in the first embodiment, two bus drivers connected to the bus supply logic signals different from each other to the bus, so that a flow-through current flows through the path including the two bus drivers and the bus. In contrast, in the semiconductor device 4 according to this embodiment, a flow-through current flows through a path including the bus driver D0 and the bus B0 using the verification circuit 45 connected to the bus B0. As the configuration and operation of the semiconductor device 4 of this embodiment other than the above point are the same as those of the semiconductor device 1 described in the first embodiment, the repeated descriptions will be omitted as appropriate.

As shown in FIG. 18, the semiconductor device 4 according to this embodiment includes at least a bus B0, a logic module 41, and the verification circuit 45. Note that, in the semiconductor device 4 shown in FIG. 18, only the components necessary for describing this embodiment are described, and descriptions of other commonly known components are omitted. In this embodiment, for example, the semiconductor device 4 is, for example, a logic LSI and a microcomputer manufactured using CMOS technology.

Like the semiconductor device according to the first embodiment, in the semiconductor device 4 according to this embodiment, an abnormality in the semiconductor device 4 is detected by measuring the static power supply current (Iddq) of the semiconductor device 4. In FIG. 18, the descriptions of the power supply 110, the current measurement circuit 111, and the abnormality determination circuit 112 (see FIG. 1) are omitted.

As shown in FIG. 18, the logic module 41 includes the bus driver D0 for driving the bus B0. Specifically, the output terminal of the bus driver D0 is connected to the bus B0, and outputs the logic signals inside the logic module 41 to the bus B0. That is, the bus driver D0 functions as an output bus driver for outputting the logic signals inside the logic module 41 to the bus B0. As in the case described in the first embodiment, the bus driver D0 may be composed of a tri-state buffer. Note that descriptions of other circuit elements (logic circuits, drivers for inputting signals from the bus, etc.) included in the logic module 41 are omitted.

The verification circuit 45 is configured to supply, to the bus B0, a logic signal opposite to the logic signal that the bus driver D0 supplies to the bus B0. As shown in FIG. 18, the verification circuit 45 can be composed using a tri-state inverter 46 and inverters INV11 and INV12.

The tri-state inverter 46 can be composed using P-channel transistors MP11 and MP12, N-channel transistors MN11 and MN12, and an inverter INV13.

The source of the P-channel transistor MP11 is connected to the power supply line on the high potential side, and the drain of the P-channel transistor MP11 is connected to the source of the P-channel transistor MP12. The drain of the P-channel transistor MP12 is connected to the bus B0. The drain of the N-channel transistor MN11 is connected to the bus B0, and the source of the N-channel transistor MN11 is connected to the drain of the N-channel transistor MN12. The source of the N-channel transistor MN12 is connected to the power supply line on the low potential side.

The output of the inverter INV12 is connected to the gate of the P-channel transistor MP11 and the gate of the N-channel transistor MN12 (corresponding to the input of the tri-state inverter 46).

An enable signal EN is supplied to an input of the inverter INV13. Further, the inverter INV13 supplies a signal obtained by inverting the enable signal EN to the gate of the P-channel transistor MP12. The enable signal EN is supplied to the gate of the N-channel transistor MN11.

When the enable signal EN is at the low level, the P-channel transistor MP12 and the N-channel transistor MN11 are turned off. In this case, the output of the tri-state inverter 46 is in a floating state, resulting in a high impedance state.

On the other hand, when the enable signal EN is at the high level, the P-channel transistor MP12 and the N-channel transistor MN11 are turned on. In this case, the tri-state inverter 46 functions as an inverter (an inverting logic circuit).

As shown in FIG. 18, an output terminal of the tristate inverter 46 is connected to the bus B0, and an even number of inverters (i.e., the inverters INV11 and INV12) are connected in series between the output terminal and an input terminal of the tri-state inverter 46. In other words, the verification circuit 45 is composed using an odd number of inverters (three inverters in the case of FIG. 18) connected in series, and input terminal and output terminal of the odd number of the inverters are connected to the bus B0 to constitute a feedback circuit. Therefore, when the high-level enable signal EN is supplied to the tri-state inverter 46, the verification circuit 45 tries to supply, to the bus B0, the logic signal opposite to the logic signal that the bus driver D0 supplies to the bus B0.

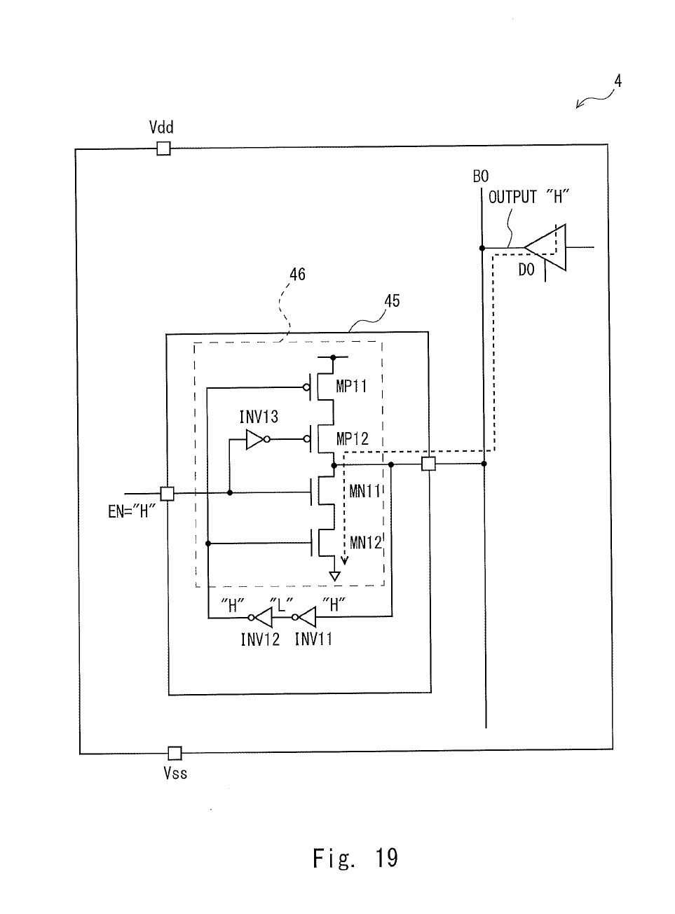

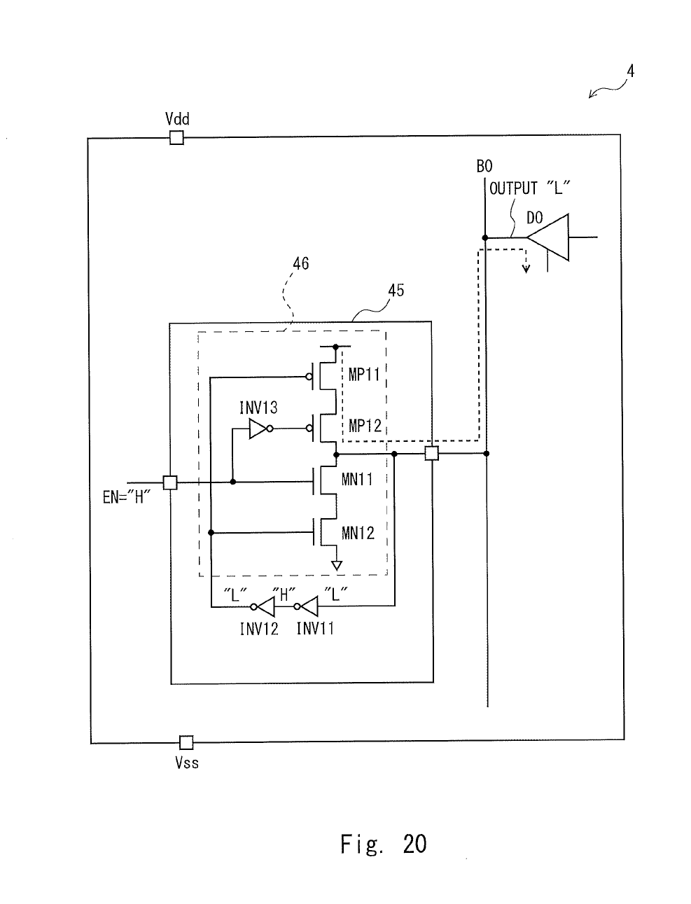

FIGS. 19 and 20 are views for describing an operation of the semiconductor device according to this embodiment. For example, as shown in FIG. 19, when the bus driver D0 outputs a high-level logic signal to the bus B0 while the enable signal EN supplied to the verification circuit 45 is at the high level, a high-level signal is supplied to the verification circuit 45. In this case, as the input of the inverter INV11 is brought to a high level, a high-level signal is output from the inverter INV12. At this time, the high-level signal is supplied to each of the gate of the P-channel transistor MP11 and the gate of the N-channel transistor MN12 of the tri-state inverter 46. Therefore, the P-channel transistor MP11 is turned off, and the N-channel transistor MN12 is turned on, and the tri-state inverter 46 tries to output a low-level signal to the bus B0.

Normally, the output becomes unstable in a loop composed of an odd number of inverters. However, as this embodiment aims to check the operation of the bus driver D0 and check the conduction of the bus B0, the verification circuit 45 only needs to allow a constant current to flow through the semiconductor device. Thus, it is not necessary to compete with the bus driver D0 and invert the potential of the bus B0. Therefore, in this embodiment, the driving force of the tri-state inverter 46 is configured to be smaller than the driving force of the bus driver D0.

For example, the transistor size of each of the transistors MP11, MP12, MN11, and MN12 constituting the tri-state inverter 46 is configured to be smaller than the transistor size of each transistor constituting the bus driver D0.

With such a configuration, as shown in FIG. 19, a flow-through current flows from the bus driver D0 to the verification circuit 45. Specifically, a flow-through current can flow through the bus driver D0, the bus B0, and the N-channel transistors MN11 and MN12.

In this embodiment, the operation of the bus driver D0, specifically, the operations of the P-channel transistors MP1 and MP2 of the bus driver D0 (see FIG. 2), and a connection state of the wiring from the bus driver D0 to the verification circuit 45 can be evaluated by measuring the flow-through current flowing at this time. For example, when the measured amount of the flow-through current is less than or equal to the predetermined reference value, at least one of the bus B0 and the bus driver D0 can be determined to be abnormal.

As shown in FIG. 20, when the bus driver D0 is outputting a low-level logic signal to the bus B0 while the enable signal EN supplied to the verification circuit 45 is at the high level, a low-level signal is supplied to the verification circuit 45. In this case, as the input of the inverter INV11 is brought to a low level, a low-level signal is output from the inverter INV12. At this time, a low-level signal is supplied to each of the gate of the P-channel transistor MP11 and the gate of the N-channel transistor MN12 of the tri-state inverter 46. Therefore, the P-channel transistor MP11 is turned on, the N-channel transistor MN12 is turned off, and the tri-state inverter 46 tries to output a high-level signal to the bus B0.

In this case, a flow-through current flows from the verification circuit 45 toward the bus driver D0. Specifically, a flow-through current flows through the P-channel transistors MP11 and MP12, the bus B0, and the bus driver D0.

In this embodiment, the operation of the bus driver D0, specifically, the operations of the N-channel transistors MN1 and MN2 of the bus driver D0 (see FIG. 2), and a connection state of the wiring from the bus driver D0 to the verification circuit 45 can be evaluated by measuring the flow-through current flowing at this time. For example, when the measured amount of the flow-through current is less than or equal to the predetermined reference value, at least one of the bus B0 and the bus driver D0 can be determined to be abnormal.

As described above, in the semiconductor device 4 according to this embodiment, the verification circuit 45 is connected to the bus B0, and a flow-through current flows through the path including the bus driver D0 and the bus B0. Then, an abnormality in at least one of the bus B0 and the bus driver D0 is detected based on the amount of the flow-through current. This simplifies the operation test of the semiconductor device and shortens the time required for the operation test.

As described above, in the semiconductor device 4 according to this embodiment, the verification circuit 45 is configured to supply, to the bus B0, a logic signal opposite to a logic signal supplied by the bus driver D0 to the bus B0. This eliminates the need for a signal line to control the logic signal output from the verification circuit 45 to the bus B0 and a control circuit for the signal line, thereby simplifying the circuit configuration.

### Fifth Embodiment

Next, a fifth embodiment will be described.

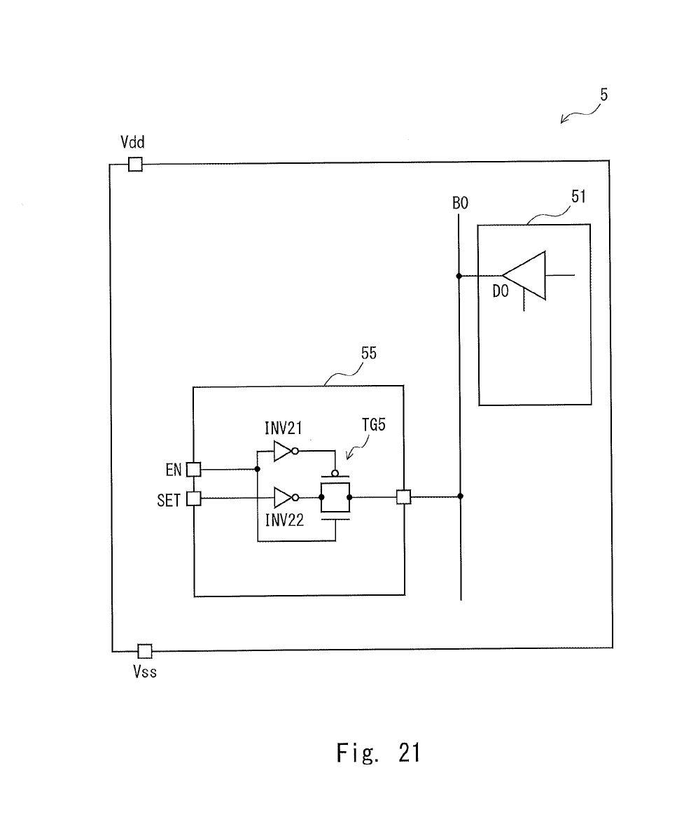

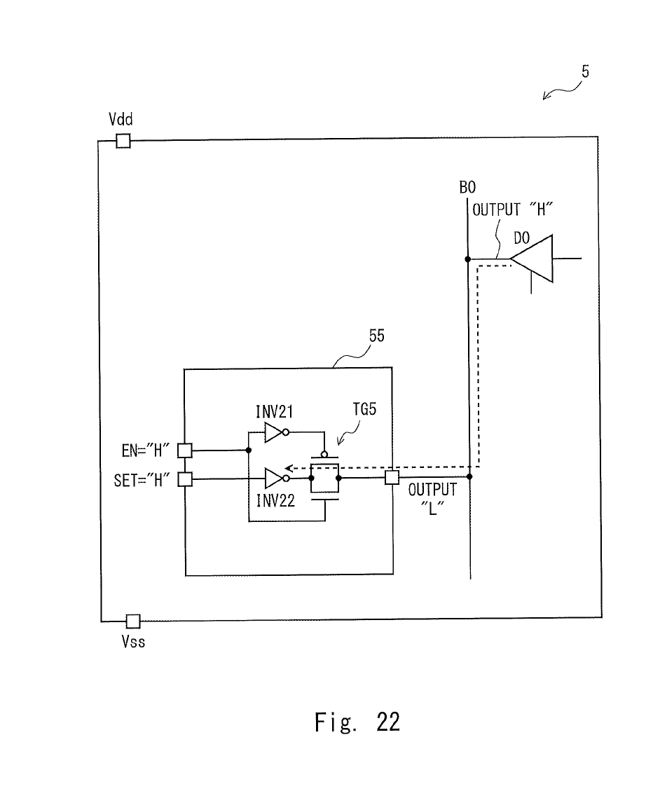

FIG. 21 is a view for describing a semiconductor device according to the fifth embodiment. In the semiconductor device 5 according to the fifth embodiment, a configuration of a verification circuit 55 differs from that of the semiconductor device 4 described in the fourth embodiment. As the configuration and operation of the semiconductor device 5 of this embodiment other than the above point are the same as those of the semiconductor device 4 described in the fourth embodiment, the repeated descriptions will be omitted as appropriate.

As shown in FIG. 21, the semiconductor device 5 according to this embodiment includes at least a bus B0, a logic module 51, and the verification circuit 55. Note that, in the semiconductor device 5 shown in FIG. 21, only the components necessary for describing this embodiment are described, and descriptions of other commonly known components are omitted. In this embodiment, the semiconductor device 5 is, for example, a logic LSI and a microcomputer manufactured using CMOS technology.

Like the semiconductor device according to the first embodiment, in the semiconductor device 5 according to this embodiment, an abnormality in the semiconductor device 5 is detected by measuring the static power supply current (Iddq) of the semiconductor device 5. In FIG. 21, the descriptions of the power supply 110, the current measurement circuit 111, and the abnormality determination circuit 112 (see FIG. 1) are omitted.

As shown in FIG. 21, the logic module 51 includes the bus driver D0 for driving the bus B0. Specifically, the output terminal of the bus driver D0 is connected to the bus B0, and outputs the logic signals inside the logic module 51 to the bus B0. That is, the bus driver D0 functions as an output bus driver for outputting the logic signals inside the logic module 51 to the bus B0. As in the case described in the first embodiment, the bus driver D0 may be composed of a tri-state buffer. Note that descriptions of other circuit elements (logic circuits, drivers for inputting signals from the bus, etc.) included in the logic module 51 are omitted.

The verification circuit 55 is configured to be able to supply, to the bus B0, a logic signal opposite to the logic signal that the bus driver D0 supplies to the bus B0. As shown in FIG. 21, the verification circuit 55 includes inverters INV21 and INV22 and a switching element TG5. The switching element TG5 can be composed using, for example, a transfer gate.

The switching element TG5 is switched between a state in which the logic signal is output to the bus B0 and a state of high impedance according to the enable signal EN.

Specifically, when the enable signal EN supplied to the verification circuit 55 is at the low level, a low-level signal is supplied to the gate of the N-channel transistor constituting the switching element TG5. A signal (a high-level signal) obtained by inverting the enable signal EN by the inverter INV21 is supplied to the gate of the P-channel transistor constituting the switching element TG5. Therefore, in this case, the P-channel transistor MP12 and the N-channel transistor MN11 are turned off, and the output of the verification circuit 55 becomes high impedance.

On the other hand, when the enable signal EN supplied to the verification circuit 55 is at the high level, a high-level signal is supplied to the gate of the N-channel transistor constituting the switching element TG5. Further, a signal (a low-level signal) obtained by inverting the enable signal EN by the inverter INV21 is supplied to the gate of the P-channel transistor constituting the switching element TG5. Therefore, in this case, the P-channel transistor MP12 and the N-channel transistor MN11 are turned on, and the output of the inverter INV22 is connected to the bus B0.

Further, the inverter INV22 outputs a logic signal corresponding to a polarity setting signal SET to the bus B0. Specifically, when the polarity setting signal SET is at the high level, the inverter INV22 outputs a low-level logic signal to the bus B0. On the other hand, when the polarity setting signal SET is at the low level, the inverter INV22 outputs a high-level logic signal to the bus B0. In FIG. 21, the verification circuit 55 includes the inverter INV22. However, in this embodiment, a driver (i.e., a driver not inverting signals) may be used instead of the inverter INV22. In this case, the polarity setting signal SET is set contrary to the polarity setting signal SET when the inverter INV22 is used.

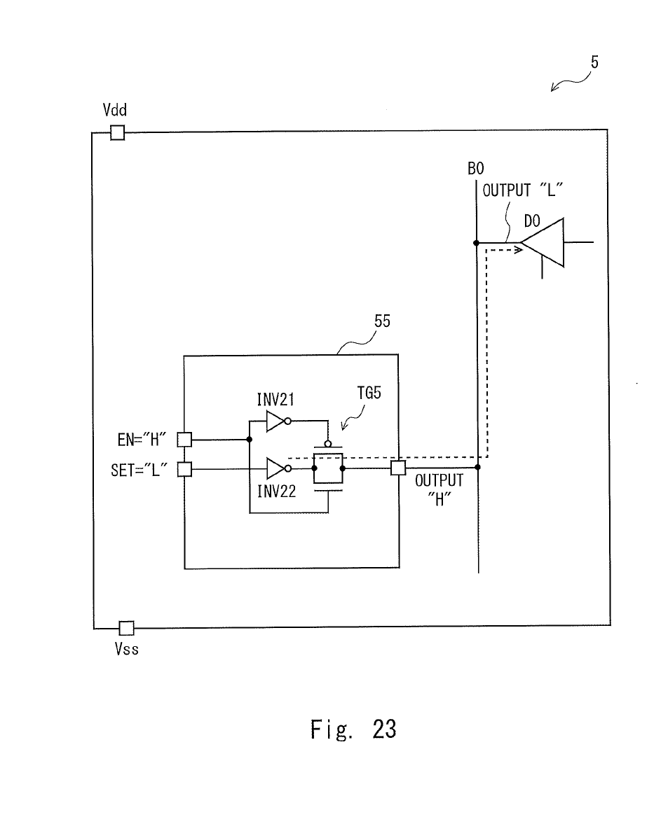

FIGS. 22 and 23 are views for describing the operation of the semiconductor device 5 according to this embodiment. As shown in FIG. 22, in order to conduct the operation test while the bus driver D0 is outputting a high-level logic signal to the bus B0, the high-level enable signal EN and the high-level polarity setting signal SET are supplied to the verification circuit 55.

When the high-level enable signal EN is supplied to the verification circuit 55, the switching element TG5 is turned on, and an output of the inverter INV22 is connected to the bus B0. Further, when the high-level polarity setting signal SET is supplied to the verification circuit 55, the inverter INV22 outputs a low-level logic signal to the bus B0.

As this embodiment aims to check the operation of the bus driver D0 and check the conduction of the bus B0, the verification circuit 55 only needs to allow a constant current to flow through the semiconductor device. Thus, it is not necessary to compete with the bus driver D0 and invert the potential of the bus B0. Therefore, in this embodiment, the driving force of the inverter INV22 is configured to be smaller than the driving force of the bus driver D0.

For example, the transistor size of each transistor constituting the inverter INV22 is configured to be smaller than the transistor size of each transistor constituting the bus driver D0.

With such a configuration, a flow-through current flows from the bus driver D0 toward the verification circuit 55. Specifically, a flow-through current can flow through the bus driver D0, the bus B0, the switching element TG5, and the inverter INV22.

In this embodiment, the operation of the bus driver D0, specifically, the operations of the P-channel transistors MP1 and MP2 of the bus driver D0 (see FIG. 2), and a connection state of the wiring from the bus driver D0 to the verification circuit 55 can be evaluated by measuring the flow-through current flowing at this time. For example, when the measured amount of the flow-through current is less than or equal to the predetermined reference value, at least one of the bus B0 and the bus driver D0 can be determined to be abnormal. Further, the driving force of the bus driver D0 can be evaluated by evaluating the measured amount of the flow-through current.

As shown in FIG. 23, in order to conduct the operation test while the bus driver D0 is outputting a low-level logic signal to the bus B0, the high-level enable signal EN and the low-level polarity setting signal SET are supplied to the verification circuit 55.

When the high-level enable signal EN is supplied to the verification circuit 55, the switching element TG5 is turned on, and the output of the inverter INV22 is connected to the bus B0. Further, when the low-level polarity setting signal SET is supplied to the verification circuit 55, the inverter INV22 outputs a high-level logic signal to the bus B0.

With such a configuration, a flow-through current flows from the verification circuit 55 toward the bus driver D0. Specifically, a flow-through current can flow through the inverter INV22, the switching element TG5, the bus B0, and the bus driver D0.

Likewise, in the case shown in FIG. 23, the operation of the bus driver D0, specifically, the operations of the N-channel transistors MN1 and MN2 of the bus driver D0 (see FIG. 2), and a connection state of the wiring from the verification circuit 55 to the bus driver D0 can be evaluated by measuring the flow-through current flowing at this time. For example, when the measured amount of the flow-through current is less than or equal to the predetermined reference value, at least one of the bus B0 and the bus driver D0 can be determined to be abnormal. Further, the driving force of the bus driver D0 can be evaluated by evaluating the measured amount of the flow-through current.

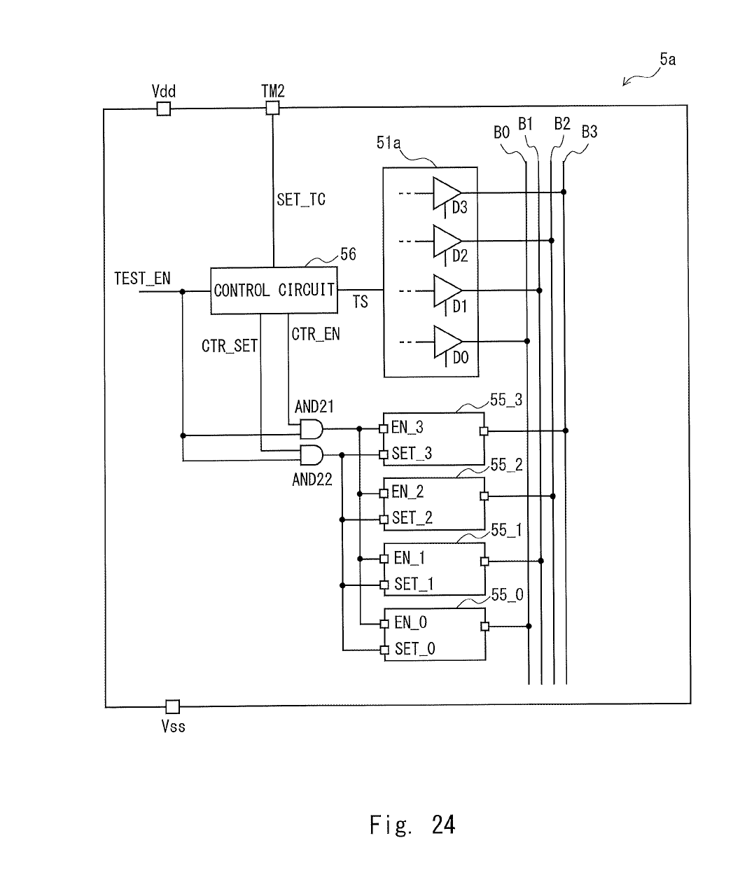

FIG. 24 is a view showing another configuration example of the semiconductor device according to this embodiment. A semiconductor device 5a shown in FIG. 24 includes a logic module 51a. The logic module 51a includes a plurality of buses B0 to B3 and a plurality of bus drivers D0 to D3. The respective bus drivers D0 to D3 are connected to the buses B0 to B3, respectively. Verification circuits 55_0 to 55_3 are connected to the buses B0 to B3, respectively. The verification circuits 55_0 to 55_3 correspond to the verification circuit 55 described with reference to FIGS. 21 to 23.

An enable signal is supplied from the logical conjunction AND21 to the enable signal terminals EN_0 to EN_3 of the respective verification circuits 55_0 to 55_3. A polarity setting signal is supplied from the logical conjunction AND22 to the polarity setting terminals SET_0 to SET_3 of the respective verification circuits 55_0 to 55_3.

The control circuit 56 supplies an enable control signal CTR_EN to one input of the logical conjunction AND21. Further, the control circuit 56 supplies the polarity setting control signal CTR_SET to one input of the logical conjunction AND22. Furthermore, a test enable signal TEST_EN is supplied to the other inputs of the logical conjunctions AND21 and AND22.

When the operation test is conducted, the control circuit 25 controls the bus drivers D0 to D3 by supplying the test signal TS to the logic module 51a. Setting information SET_TC of the operation test is supplied to the control circuit 56 via a test terminal TM2. Further, a test enable signal TEST_EN is supplied to the control circuit 56.

When the operation test is conducted on the semiconductor device 5a, the test enable signal TEST_EN is brought to a high level. In this state, when the high-level enable control signal CTR_EN is supplied from the control circuit 56, the logical conjunction AND21 supplies a high-level enable signal to enable signal terminals EN_0 to EN_3 of the respective verification circuits 55_0 to 55_3. Then, the switching element TG5 (see FIG. 21) of each of the verification circuits 55_0 to 55_3 is turned on.

Further, when a high-level polarity setting control signal CTR_SET is supplied from the control circuit 56, the logical conjunction AND22 supplies a high-level polarity setting signal to the polarity setting terminals SET_0 to SET_3 of the respective verification circuits 55_0 to 55_3. In this case, the verification circuits 55_0 to 55_3 output low-level logic signals to the buses B0 to B3, respectively. In this state, the control circuit 56 controls the bus driver D0 to output a high-level logic signal from the bus driver D0, which is subject to the operation test (in this case, the bus driver D0 is subject to the operation test as an example), to the bus B0. At this time, the control circuit 56 controls the bus drivers D1 to D3, which are not subject to the operation test, to output low-level logic signals. Then, a flow-through current flows from the bus driver D0, which is subject to the operation test, to the verification circuit 55_0. The bus driver D0 and the bus B0 can be evaluated by measuring the amount of this flow-through current.

On the other hand, when a low-level polarity setting control signal CTR_SET is supplied from the control circuit 56, the logical conjunction AND22 supplies a low-level polarity setting signal to the polarity setting terminals SET_0 to SET_3 of the respective verification circuits 55_0 to 55_3. In this case, the verification circuits 55_0 to 55_3 output high-level logic signals to the buses B0 to B3, respectively. In this state, the control circuit 56 controls the bus driver D0 to output a low-level logic signal from the bus driver D0, which is subject to the operation test (in this case, the bus driver D0 is subject to the operation test as an example), to the bus B0. At this time, the control circuit 56 controls the bus drivers D1 to D3, which are not subject to the operation test, to output high-level logic signals. Then, a flow-through current flows from the verification circuit 55_0 to the bus driver D0, which is subject to the operation test. The bus driver D0 and the bus B0 can be evaluated by measuring the amount of this flow-through current.

As described above, in the semiconductor devices 5 and 5a according to this embodiment, the verification circuits 55 are connected to the buses, the flow-through current flows through the path including the bus drivers and the buses, and an abnormality in at least one of the buses and the bus drivers is detected based on the amount of the flow-through current. This simplifies the operation test of the semiconductor device and shortens the time required for the operation test.

The first to fifth embodiments can be combined as desirable by one of ordinary skill in the art.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor device comprising:
a first bus and a second bus;
a first bus driver configured to drive the first bus;
a second bus driver configured to drive the second bus;
a first switching element provided between the first bus and the second bus to be able to connect the first bus to the second bus; and
a control circuit configured to control the first and second bus drivers and the first switching element,
wherein the control circuit controls the first and second bus drivers in such a way that the first bus is connected to the second bus using the first switching element at a first timing and the first and second bus drivers supply logic signals different from each other to the first and second buses, respectively.

2. The semiconductor device according to claim 1, further comprising:
a third bus;
a third bus driver configured to drive the third bus; and
a second switching element provided between the second bus and the third bus to be able to connect the second bus to the third bus,
wherein the control circuit controls the second and third bus drivers in such a way that the second bus is connected to the third bus using the second switching element at a second timing and the second and third bus drivers supply logic signals different from each other to the second and third buses, respectively.

3. A semiconductor device comprising:
a bus;
a bus driver configured to drive the bus; and
a verification circuit connected to the bus,
wherein, in response to an input of a logic signal from the bus driver to the bus, the verification circuit is configured to try supplying, to the bus, a logic signal opposite to the logic signal supplied from the bus driver to the bus.

4. The semiconductor device according to claim 3, wherein
the verification circuit is composed using an odd number of inverters connected in series,
input terminal and output terminal of the odd number of the inverters are connected to the bus, and
a driving force of the last stage inverter among the odd number of the inverters is smaller than a driving force of the bus driver.

5. The semiconductor device according to claim 3, wherein
the verification circuit comprises:
a tri-state inverter, an output terminal of which is connected to the bus; and
an even number of inverters connected in series between an input terminal and the output terminal of the tri-state inverter,
wherein a driving force of the tri-state inverter is smaller than the driving force of the bus driver.

6. A semiconductor device according to claim 3, wherein
the verification circuit comprises:
a switching element configured to switch between a state in which a logic signal is output to the bus and a state of high impedance according to an enable signal; and
a driver configured to output the logic signal corresponding to a polarity setting signal to the bus,
wherein a driving force of the driver is smaller than the driving force of the bus driver.

7. A method of testing a semiconductor device comprising a bus and first and second bus drivers configured to drive the bus, the method comprising:
supplying, from the first and second bus drivers, logic signals different from each other to the bus; and
detecting an amount of a current flowing when the first and second bus drivers supply the logic signals different from each other to the bus.

8. A method of testing a semiconductor device comprising a first bus and a second bus, a first bus driver configured to drive the first bus, a second bus driver configured to drive the second bus, and a first switching element provided between the first bus and the second bus to be able to connect the first bus to the second bus, the method comprising:
connecting the first bus to the second bus using the first switching element; and
detecting an amount of a current flowing when the first and second bus drivers supply logic signals different from each other to the first and second buses, respectively.

9. A method of testing a semiconductor device comprising a bus, a bus driver configured to drive the bus, and a verification circuit connected to the bus, the method comprising:
trying to supply, from the verification circuit to the bus, a logic signal opposite to a logic signal supplied from the bus driver to the bus; and
detecting an amount of a current flowing through the bus driver, the bus, and the verification circuit when the bus driver supplies the logic signal to the bus.
